(19) United States
(12) Patent Application Publication
(10) Pub. No.: US 2024/0153574 A1
(43) Pub. Date: May 9, 2024

(54) NON-VOLATILE XNOR AND NON-VOLATILE SRAM SYSTEM WITH ENHANCED STORE CAPABILITY FOR MEMORY AND IN-MEMORY COMPUTE BNN APPLICATIONS AND METHODS OF USE

(71) Applicant: American University of Beirut, Beirut (LB)

(72) Inventors: Rouwaida Kanj, Cedar Park, TX (US); Zeinab Soueidan, Beirut (LB)

(21) Appl. No.: 18/503,530

(22) Filed: Nov. 7, 2023

Related U.S. Application Data
(60) Provisional application No. 63/382,572, filed on Nov. 7, 2022.

(51) Int. Cl. G11C 29/14; G11C 11/54; G11C 29/12

(52) U.S. Cl. CPC G11C 29/14; G11C 11/54; G11C 29/1201

(57) ABSTRACT

Provided herein are systems and methods for a nvXNOR Cell Design with enhanced store capability for BNN applications. We propose and study two versions of the nvXNOR cell with enhanced reset capabilities. The cells introduce temporary enhanced SRAM cell pull-up capability that is only activated during the reset mechanism and does not interfere with the SRAM cell functionality. The second version improves on the first one by exploiting the XNOR cell cross-coupled pass gate structure.

### CROSS-REFERENCE TO RELATED APPLICATIONS

The present application claims priority to U.S. provisional application Ser. No. 63/382,572, filed Nov. 7, 2022, herein incorporated by reference in its entirety.

### BACKGROUND

The invention generally relates to non-volatile static random access memory architectures.

Resistive random access memory (RRAM) relates flux to charge, where w is the state variable and a memristor includes a high packing density 100 Gb/cm². The memristor includes a small Space action metric (J·ns·nm³), nonvolatility, and the ability to store multiple analog levels.

RRAM cell is a Metal-Insulator-Metal device. For OxRAM, the resistance depends on a soft breakdown phenomenon where oxygen atoms are split into oxygen ions and vacancies. Set process for the RRAM cell includes a positive set voltage is applied to the top electrode; O²⁻ ions migrate towards the electrode leaving behind V_{O}s; A CF of V_{O}s stretches from the top electrode to the bottom electrode; and the RRAM device in the LRS is shown in FIG. 1A.

Reset process for the RRAM includes a negative voltage is applied to the top electrode; O²⁻ ions migrate back to the device body; ions combine with the V_{O}s in the top portion of the filament; and a gap is created which results in an HRS for the RRAM, as shown in FIG. 1B.

RRAM programming includes factors and challenges including Retention, Endurance, and Variability and Program Instability. Retention Fail Mechanism is when memristors retention loss bears remarkable similarities to memory loss in biological systems. Depending on the program time, verify level, and temperature. The low resistance state (LRS) and the high resistance state (HRS) values drift with time. Write endurance is the # of cycles before RRAM fails to switch between LRS and HRS. Non-volatile Processors (NVP) often rely on RRAM devices and are desired for their zero-standby power operation.

RRAM devices are subject to device-to-device variations due to manufacturing process variations. They are also subject to intra-device cycle-to-cycle switching variations [15]. Cycle-to-cycle variations are governed by the intrinsic randomness of the physical mechanisms governing the set and reset processes [16], [17]. Particularly, HRS variations are mainly attributed to variations in the gap thickness and the random number of Vo (Defects) in the gap area. Due to the exponential dependency between the current in the HRS and the gap thickness, HRS statistics follow a lognormal (LG) distribution. LRS variations are attributed to the fluctuations in the number of vacancies defining the radius of the filament [18]. They typically follow a LG distribution or a bimodal distribution [19]. In low current operation, [18] noted a bimodal distribution with noticeable bending towards the reset state. The bending is attributed to fluctuations in the constriction geometry (length) of the device and the behavior is explicated as a reduction in the speed of the set process as discussed in [10], [18]. Another source of variation is the random telegraphic noise that results in sharp fluctuations in the current value and is critical in HRS [16]. The authors in [20] discuss short-term instability in low-current regimes. They denote that verify levels, and hence LRS-HRS tail separations, are lost after one second of a programming algorithm FIG. 4B and the distributions relapse back to the single pulse distributions. A detailed study shows that 5% of the population undergoes large variations. This resistance instability which is noticeable after only few hundred microseconds is attributed to geometry fluctuations of the filament which demonstrate a time decaying probability. Thus, it is recommended that program verify algorithms must incorporate longer delays for proper verify levels [20].

Endurance is affected by the Window Size. Window sizes corresponding to a Low R window where the Low resistance state (LRS) and high resistance states (HRS) are set to: 20KΩ-100KΩ/200KΩ respectively have been shown to have a high endurance equal to 10⁸ cycles. High R window 100KΩ 1 MΩ endurance equal to 10⁶ cycles. Full Range window includes 20KΩ 1 MΩ endurance equal to 10⁵ cycles. RRAM devices are also subject to variability and program instability. Program Instability is shown in FIG. 2.

The Memory Compute for Deep Neural Network (DNN) includes an input layer, several hidden layers, and an output layer. Limitations of DNN include Edge devices in IoT systems, Small mobile devices, and Power constrained platforms. A suggested Replacement for DNN is a Binary Neural Network (BNN) that includes an Idle for in memory compute, uses smaller data types, and a form of 1 bit quantization. Binary Neural Networks are one solution that reduce the memory and computational requirements of DNNs and offer similar capabilities of DNN models.

In BNNs, both the weights and activations are binarized, which reduces the memory requirement for BNNs. Using smaller data types can offer reduction in total model size. This reduces the computational complexity by bitwise operations Arithmetic with smaller data types can be quicker to compute.

In memory compute for BNN, bit wise Multiply and Accumulate operations can be performed using in memory compute.

8TXNOR Cell Overview is shown in FIG. 3A and has been proposed in [5]. Neuron value of 1/+1. WL and WLB are set to {0,Vdd}/{Vdd,0}. Weight value of 1/+1: set Q to 0/Vdd and QB to Vdd/0. Δv>0 on BL/BLB represents a 1/+1 outcome for the XNOR operation, as shown in Table 1. FIG. 3A presents an 8T XNOR SRAM cell that implements the XNOR function between the weight and the neuron as presented in Table I. The 8T cell comprises a 6T SRAM cell with two additional cross-coupled pass-gate transistors gated by WLB. WLB together with WL are used to set the value of the neuron for the cell. The weights are in turn set using Q and QB. Without loss of generality, the following is assumed 1) When the complementary wordline states WL and WLB are set to (0,Vdd)/(Vdd,0), this represents a neuron value of −1/+1 respectively; 2) a weight of −1/+1 is represented by setting Q to 0/Vdd and thus QB to Vdd/0; 3) a positive voltage drop Δv>0 on BL/BLB represents a −1/+1 outcome for the XNOR operation inline with Table 1.

To elaborate further on the outcome of the XNOR, the example of the first row of Table 1 is provided. For this example, both the input neuron and the weight are set to −1. This corresponds to WL/WLB being set to 0/Vdd. PGL2 and PGR2 will thus be ON, and WLB will connect Q and QB to the initially precharged BLB and BL respectively. Since the cell is storing a weight of ‘−1’, Q is set to 0 and this will result in discharging BLB. BLB will therefore encounter a positive voltage drop Δv>0. On the other hand, since QB is equal to Vdd, BL will encounter a ‘0’ voltage drop. This corresponds to an outcome of ‘+1’ for the bitwise XNOR. On the other hand, when the voltage drop on BLB is ‘0’ and on BL is positive, this corresponds to an outcome of ‘−1’ for the XNOR.

TABLE 1
8 T XNOR cell operation

| Neuron | Weight | Mult. | BL | BLB |
|---|---|---|---|---|
| −1 | −1 | +1 | Δυ = 0 | Δυ > 0 |
| −1 | +1 | −1 | Δυ > 0 | Δυ = 0 |
| +1 | −1 | −1 | Δυ > 0 | Δυ = 0 |
| +1 | +1 | +1 | Δυ = 0 | Δυ > 0 |

As shown in FIG. 3B, the values are as follows for the 8TXNOR cell in Table 2.

TABLE 2

| Neuron | Weight | Mult. | BL | BLB |
|---|---|---|---|---|
| −1 | −1 | +1 | Δυ = 0 | Δυ > 0 |

Nonvolatile memory enables extending the battery life of mobile chips by switching off the power supply without losing the data. P. F. Chiu et al. [12] proposed a nonvolatile-SRAM (nvSRAM) that combines the traditional SRAM cell and nonvolatile memory in one cell thereby resulting in a direct connection between volatile and non-volatile memory for fast data transfer. FIG. 4B presents the 8T-2R nvSRAM cell [12] composed of 8 transistors and 2 memristor devices. The store operation comprises two sub-operations, SET and RESET, such that the memristor neighboring the low voltage storage node gets set and the other one gets reset. This allows the memristors to store the cell values during power off. During restore mechanism, the memristors are then used to rewrite the stored value back to the cell.

Traditional nvSRAM Cell [12] includes Store and Restore Mechanisms in memory computing in energy harvesting processors, special nvSRAM cells, as shown in FIG. 4A.

For the STORE mechanism preserving SRAM value in NV memory is shown in FIG. 4B, which involves SET and RESET RESTORE including locally writing values back to SRAM cell.

The nvSRAM Cell Set Mechanism is shown in FIG. 5A; the nvSRAM Cell Equivalent Set Mechanism is shown in FIG. 5B; the nvSRAM Cell Reset Mechanism is shown in FIG. 5C; nvSRAM Cell Equivalent Reset Mechanism is shown in FIG. 5D. It improves when the PU resistance is smaller. This can be achieved by increasing the PU device. but doing this affects SRAM cell writability and balance and degrade performance.

The present invention attempts to solve these problems, as well as others.

### SUMMARY OF THE INVENTION

Provided herein are systems and methods for nvSRAM and a nvXNOR Cell Design with enhanced store capability for BNN applications.

The nvXNOR cell design comprises two versions of the nvXNOR cell with enhanced reset capabilities, wherein the cells introduce temporary enhanced SRAM cell pull-up capability that is only activated during the reset mechanism and does not interfere with the SRAM cell functionality; and the second version improves on the first version by exploiting the 8TXNOR cell cross-coupled pass gate structure.

The nvXNOR Cell Design with enhanced store capability comprises a performance of the proposed cells in terms of store capabilities, an enhanced store and hence restore yield for high endurance memristor operating windows, up to about 30% improvements in energy and energy-delay product (EDP) during store operation for the proposed designs compared to equally sized traditional 8TXnor cell. The nvXNOR Cell Design with enhanced store capability comprises two orders of magnitude improvement compared to the unsized traditional cell, which in turn allows the cell to sustain operation at the high endurance about [20-200] KΩ due to enhanced reset capability and hence maintain a good restore yield.

The nvXNOR Cell Design with enhanced store capability for BNN applications comprises an error-injection algorithm that is applied to a BNN network model developed using Larq, the cell restore yield to determine the error injection rates, the enhanced reset capability and enhanced restore yield, help maintain the BNN test accuracy compared to the traditional cell design which results in an about 8% accuracy loss in the test data. The error injection algorithm tests the implication of cell store improvement on BNN test accuracy.

The methods, systems, and apparatuses are set forth in part in the description which follows, and in part will be obvious from the description, or can be learned by practice of the methods, apparatuses, and systems. The advantages of the methods, apparatuses, and systems will be realized and attained by means of the elements and combinations particularly pointed out in the appended claims. It is to be understood that both the foregoing general description and the following detailed description are exemplary and explanatory only and are not restrictive of the methods, apparatuses, and systems, as claimed.

Accordingly, it is an object of the invention not to encompass within the invention any previously known product, process of making the product, or method of using the product such that Applicants reserve the right and hereby disclose a disclaimer of any previously known product, process, or method. It is further noted that the invention does not intend to encompass within the scope of the invention any product, process, or making of the product or method of using the product, which does not meet the written description and enablement requirements of the USPTO (35 U.S.C. § 112, first paragraph) or the EPO (Article 83 of the EPC), such that Applicants reserve the right and hereby disclose a disclaimer of any previously described product, process of making the product, or method of using the product. It may be advantageous in the practice of the invention to be in compliance with Art. 53(c) EPC and Rule 28(b) and (c) EPC. All rights to explicitly disclaim any embodiments that are the subject of any granted patent(s) of applicant in the lineage of this application or in any other lineage or in any prior filed application of any third party is explicitly reserved. Nothing herein is to be construed as a promise.

### BRIEF DESCRIPTION OF THE DRAWINGS

In the accompanying figures, like elements are identified by like reference numerals among the several preferred embodiments of the present invention.

FIG. 1A is a schematic showing the RRAM Overview: Set Mechanism for the LRS and a timing diagram sketch for the same. FIG. 1B is a schematic showing the RRAM Overview: Reset Mechanism for the HRS and a timing diagram sketch for the same.

FIG. 2 is a graph showing the RRAM program instability for the LRS and HRS as function of time.

FIG. 3A is a schematic of the 8TXNOR Cell Overview. FIG. 3B is a schematic of the 8TXNOR with the values of −1 for the neuron, −1 for the weight, +1 for the Mult. Δv=0 for BL and Δv>0 for the BLB.

FIG. 4A is a schematic diagram of a nvSRAm cell for energy harvesting processors. FIG. 4B. is a schematic of Preserving SRAM bit value in NV memory and Involves SET and RESET RESTORE: locally writing values back to SRAM cell

FIG. 5A is a schematic diagram of the nvSRAM Cell in the Set mechanism. FIG. 5B is a schematic of the nvSRAM cell in the equivalent set mechanism. FIG. 5C is a schematic of the nvSRAM cell in the Reset Mechanism. FIG. 5D is a schematic of the nvSRAM cell in the equivalent Reset Mechanism.

FIG. 6A is a schematic showing the enhanced nvSRAM Cell wherein the Pre charged PMOSs are off. FIG. 6B is a schematic showing the Enhanced nvSRAM Cell when SWL turns ON, only side of ‘0’ node activates PMOS. FIG. 6C is a schematic showing the Enhanced RESET.

FIG. 7A is a schematic and a timing diagram showing traditional nvXNOR Cell: Store and Restore Mechanisms. FIG. 7B is a graph of the Set(S)/Reset(R) Operation in traditional nvXNOR implementation adapted from nvSRAM operation in [12]. FIG. 7C is a schematic showing the traditional nvXNOR Cell: Set Mechanism. FIG. 7D is a schematic showing the traditional nvXNOR Cell: Reset Mechanism.

FIG. 8A is a schematic of the nvXNOR_enhRst Cell shown in Pre-charged PMOSs are off. FIG. 8B is a schematic of the nvXNOR_enhRst Cell: Reset Mechanism showing MPL and MPR turn on. FIG. 8C is a schematic of the nvXNOR_enhRst Cell: Reset Mechanism showing the Enhanced RESET.

FIG. 9A is a schematic of the nvXNOR_enhRst++ Cell: Overview with a simple pass gate implementation: WLB access transistor used to precharge the node. FIG. 9B is a graph for signals for proposed enhanced reset design for nvXNOR enhRst, and FIG. 9C is a graph for the signals for proposed enhanced reset design for nvXNOR enhRst++, where S stands for the set mechanism, R for the reset and P for precharge. FIG. 9D is a graph for enhanced memristor reset for the proposed nvXNOR enhRst design. Node Q maintains a higher stored value during reset when the added feedback path is activated.

FIG. 10A is a graph showing the Experimental Setup with stability and with instability; and FIG. 10B is a timing diagram for the design metrics in the Experimental setup.

FIG. 11A is a schematic diagram showing the nvSRAM. FIG. 11B is a schematic diagram showing the nvSRAM_enhRst

FIG. 12A is a schematic diagram showing nvXNOR. FIG. 12B is a schematic diagram showing nvXNOR_enhRst. FIG. 12C is a schematic diagram showing nvXNOR_enhRst++. FIG. 12D is a schematic diagram showing traditional nvXNOR redrawn to explicate 12C connections.

FIG. 13A is a graph showing the Simulation Analysis: Normalized STORE Energy. FIG. 13B is a graph showing the Analysis: Normalized STORE (energy delay product) EDP.

FIG. 14A is a graph showing the Restore Yield Analysis in the study restore yield assuming variability in R_{L}, R_{R}, PU_{L}, and PU_{R}. FIG. 14B is a graph showing the projection of Pass/Fail samples on 2-D variability space for the case of without Instability.

FIG. 15A is a graph showing the Simulation Analysis: Yield Plot without INS. FIG. 15B is a graph showing the Simulation Analysis: Yield Plot with INS.

FIG. 16A is a schematic diagram showing the BNN architecture. FIG. 16B is a graph showing the Model training accuracy and loss convergence.

FIGS. 17A and 17B are graphs showing the Model Accuracy and Loss Convergence, respectively.

FIG. 18 is a schematic diagram showing the BNN Error Injection Algorithm.

FIG. 19 is a table and graph showing the Test Accuracy After Error Injection.

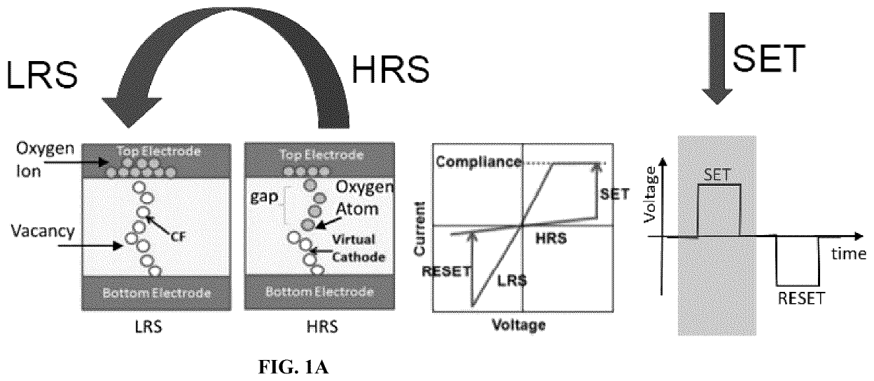

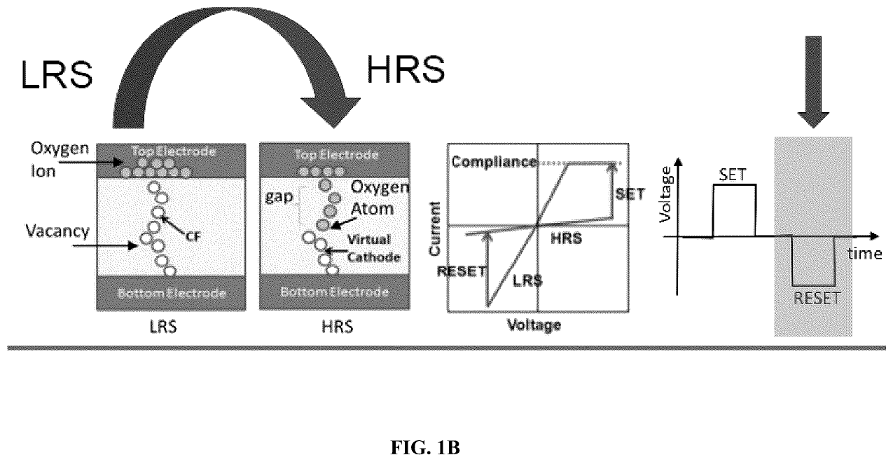

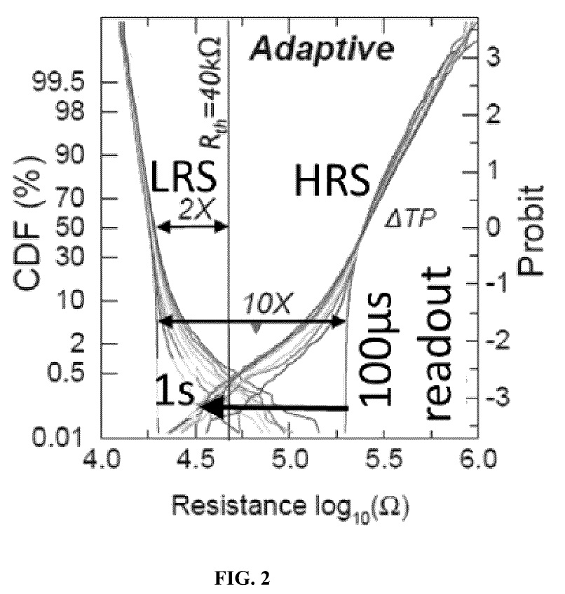

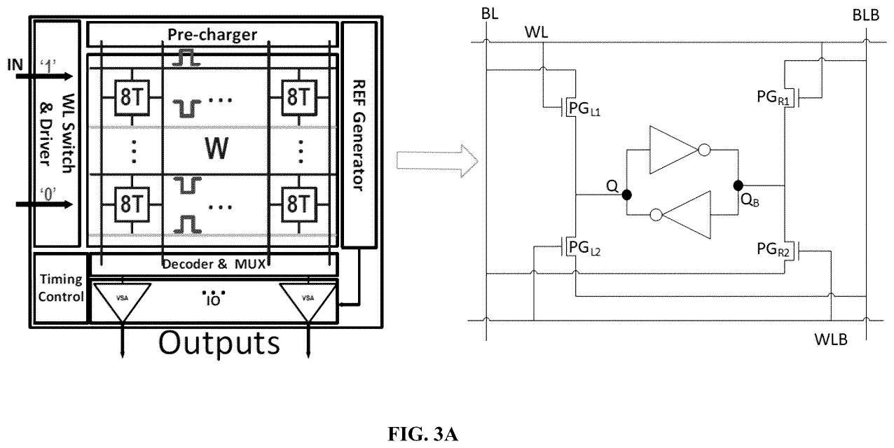

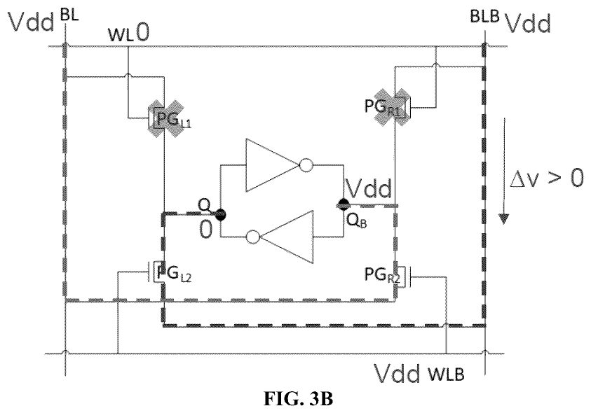

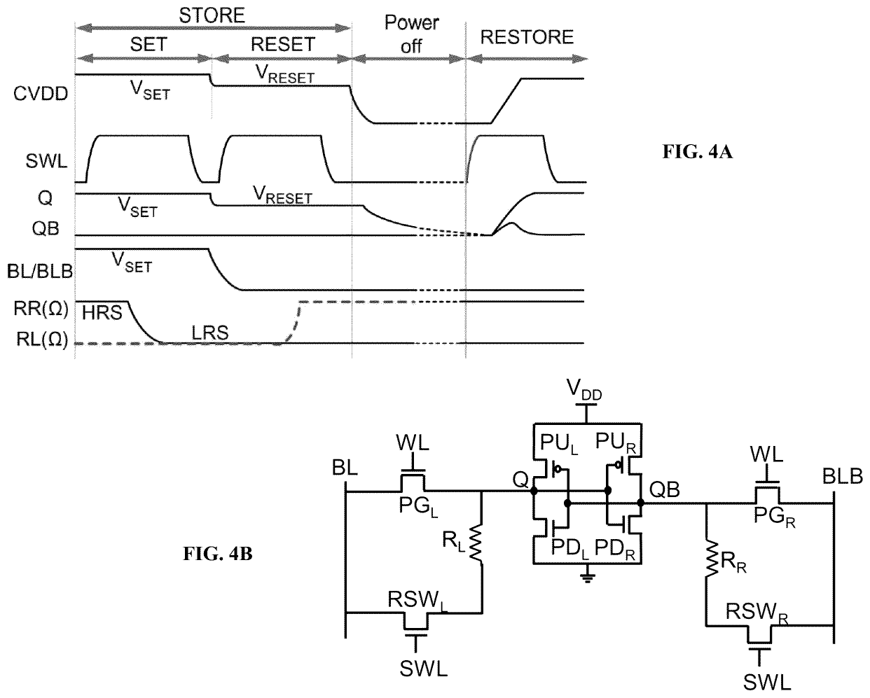

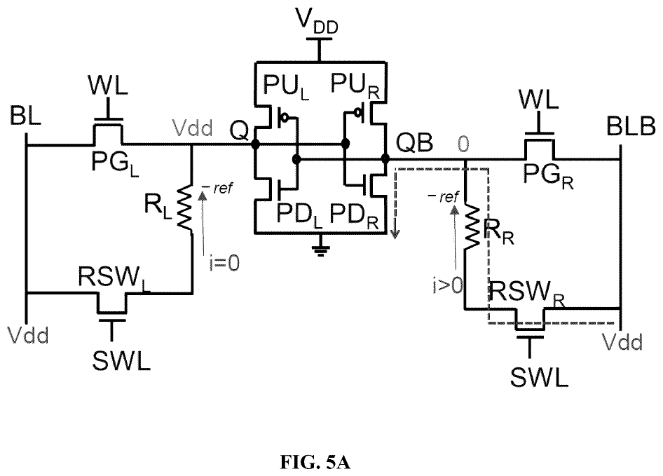

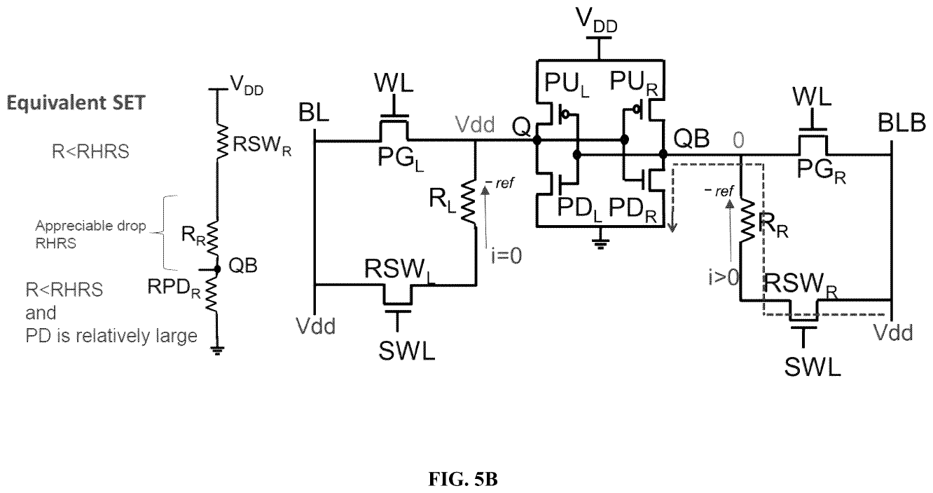

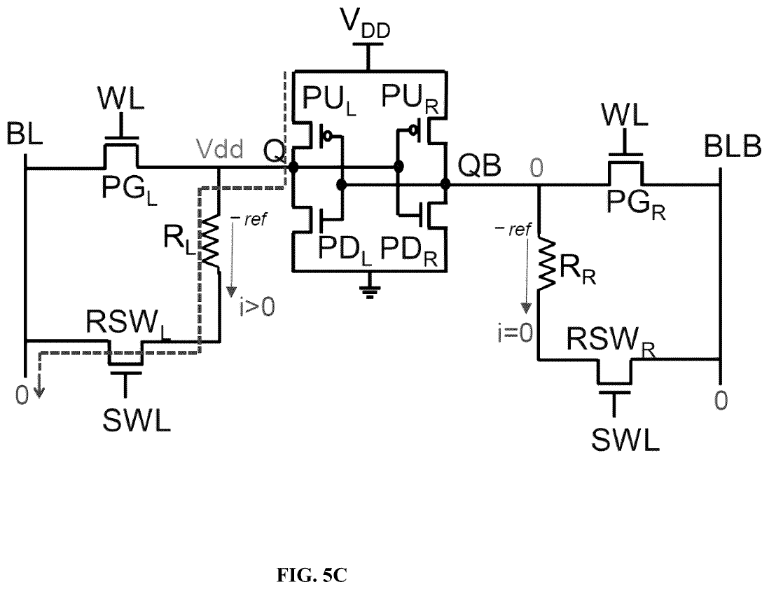

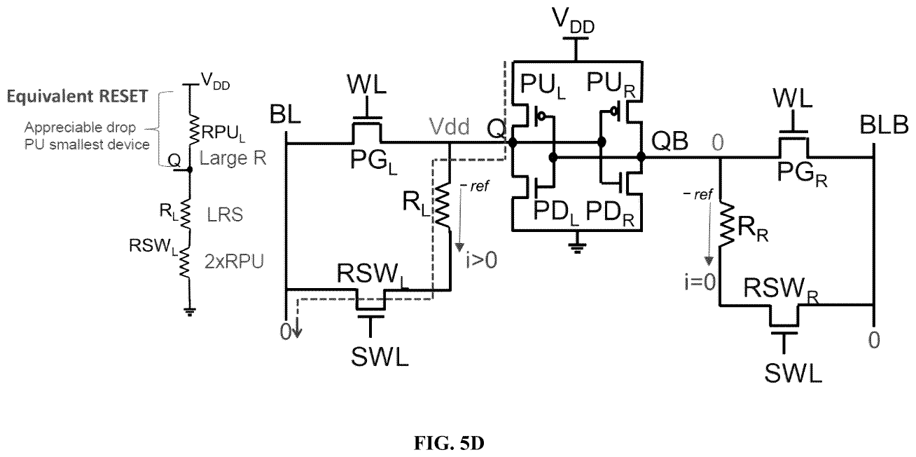

### DETAILED DESCRIPTION OF THE INVENTION

The foregoing and other features and advantages of the invention are apparent from the following detailed description of exemplary embodiments, read in conjunction with the accompanying drawings. The detailed description and drawings are merely illustrative of the invention rather than limiting, the scope of the invention being defined by the appended claims and equivalents thereof.

Embodiments of the invention will now be described with reference to the Figures, wherein like numerals reflect like elements throughout. The terminology used in the description presented herein is not intended to be interpreted in any limited or restrictive way, simply because it is being utilized in conjunction with detailed description of certain specific embodiments of the invention. Furthermore, embodiments of the invention may include several novel features, no single one of which is solely responsible for its desirable attributes or which is essential to practicing the invention described herein.

The use of the terms “a” and “an” and “the” and similar referents in the context of describing the invention are to be construed to cover both the singular and the plural, unless otherwise indicated herein or clearly contradicted by context. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

Recitation of ranges of values herein are merely intended to serve as a shorthand method of referring individually to each separate value falling within the range, unless otherwise indicated herein, and each separate value is incorporated into the specification as if it were individually recited herein. The word “about,” when accompanying a numerical value, is to be construed as indicating a deviation of up to and inclusive of 10% from the stated numerical value. The use of any and all examples, or exemplary language (“e.g.” or “such as”) provided herein, is intended merely to better illuminate the invention and does not pose a limitation on the scope of the invention unless otherwise claimed. No language in the specification should be construed as indicating any nonclaimed element as essential to the practice of the invention.

References to “one embodiment,” “an embodiment,” “example embodiment,” “various embodiments,” etc., may indicate that the embodiment(s) of the invention so described may include a particular feature, structure, or characteristic, but not every embodiment necessarily includes the particular feature, structure, or characteristic. Further, repeated use of the phrase “in one embodiment,” or “in an exemplary embodiment,” do not necessarily refer to the same embodiment, although they may.

As used herein the term “method” refers to manners, means, techniques and procedures for accomplishing a given task including, but not limited to, those manners, means, techniques and procedures either known to, or readily developed from known manners, means, techniques and procedures by practitioners of the electrical, software, and mechanical arts. Unless otherwise expressly stated, it is in no way intended that any method or aspect set forth herein be construed as requiring that its steps be performed in a specific order. Accordingly, where a method claim does not specifically state in the claims or descriptions that the steps are to be limited to a specific order, it is no way intended that an order be inferred, in any respect. This holds for any possible non-express basis for interpretation, including matters of logic with respect to arrangement of steps or operational flow, plain meaning derived from grammatical organization or punctuation, or the number or type of aspects described in the specification.

### DESCRIPTION OF EMBODIMENTS

Generally speaking, two versions of the nvXNOR cell with enhanced reset capabilities for BNN applications along with a respective nvSRAM cell with enhanced reset capability are disclosed herein. The nvXNOR cells include a store capability and store capability performance. The nvXNOR cells include an enhanced store on the restore yield for high endurance memristor operating windows. An error injection algorithm is applied to a BNN network model developed using Larq to test the significance of improvement.

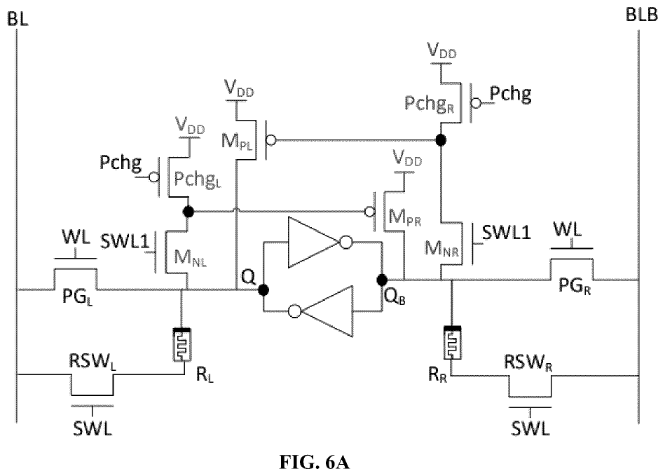

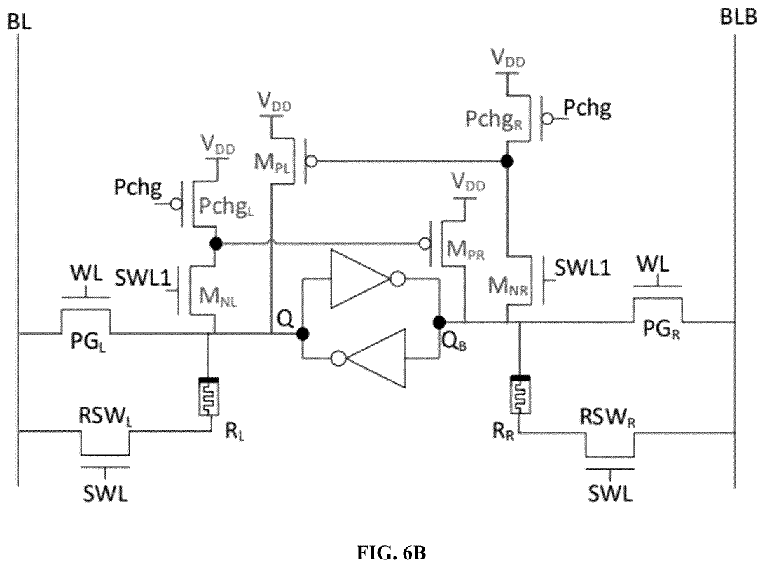

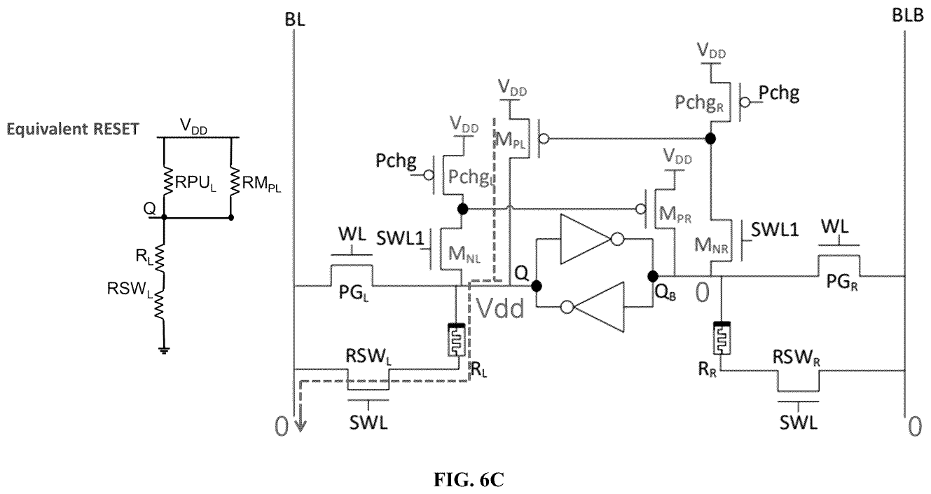

A nvSRAM with Efficient Restore is disclosed that maintains SRAM cell integrity and enhances the RESET mechanism, while targeting enhanced endurance. The enhanced nvSRAM Cell is shown in FIG. 6A, wherein the Pre charged PMOSs are off. FIG. 6B shows the Enhanced nvSRAM Cell when SWL turns ON, only side of ‘0’ node activates PMOS. FIG. 6C shows the Enhanced RESET.

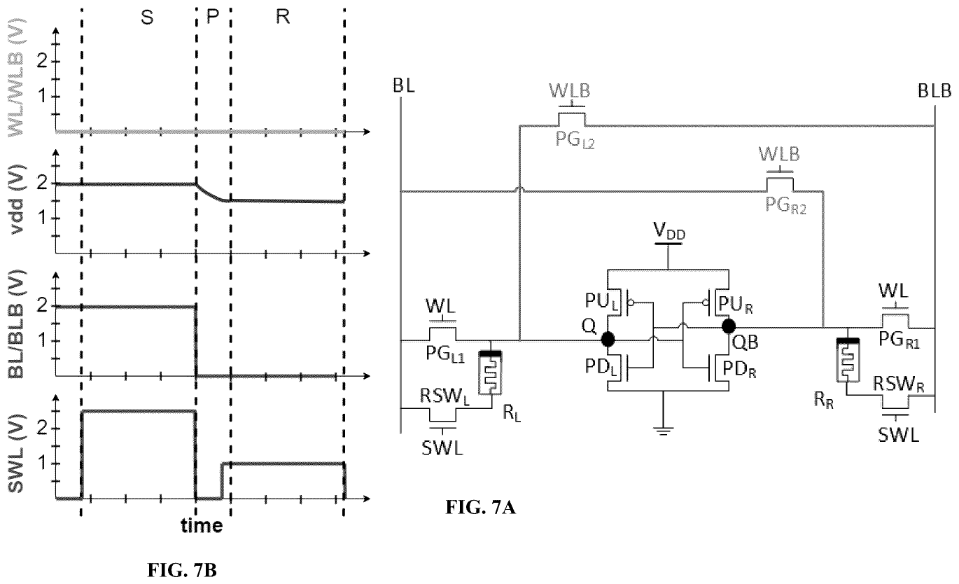

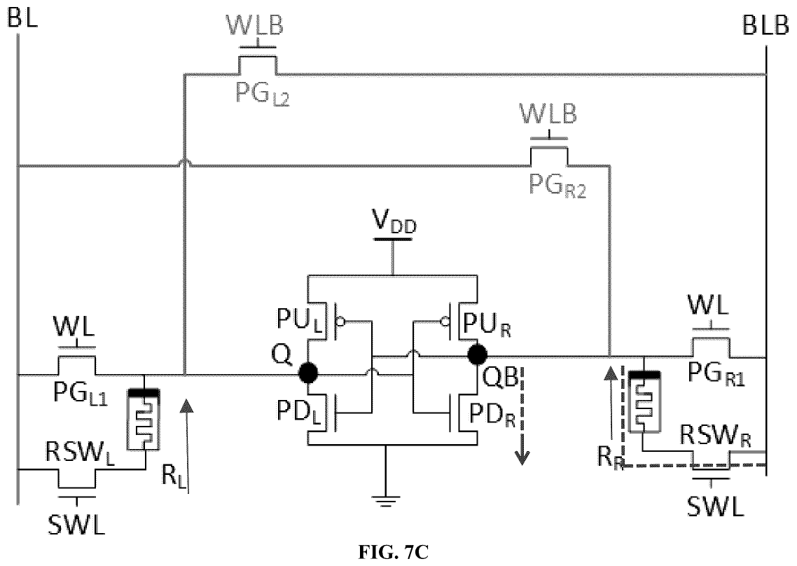

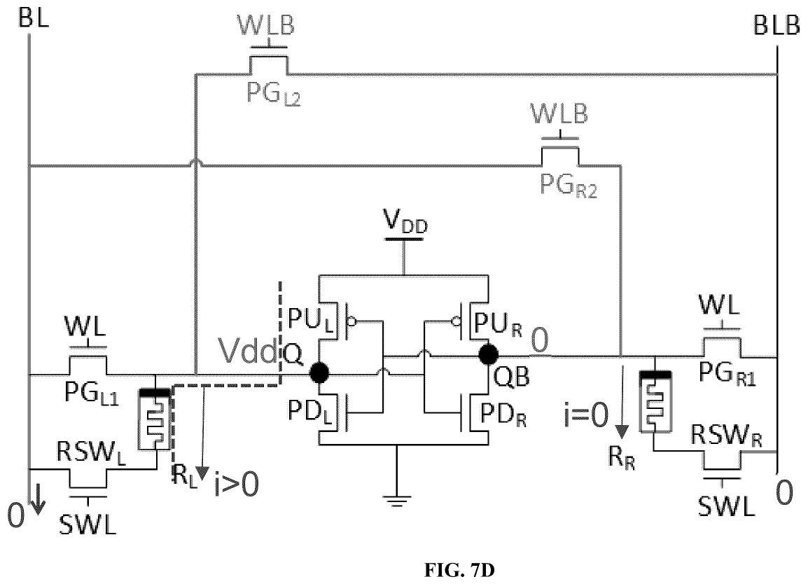

Traditional nvXNOR Cell at the core have an SRAM cell and undergo Store and Restore Mechanisms as shown in FIGS. 7A-7B. Traditional nvXNOR Cell: Set Mechanism is shown in FIG. 7C. Traditional nvXNOR Cell: Reset Mechanism is shown in FIG. 7D.

FIG. 7A presents a non-volatile 8T XNOR (nvXNOR) cell based on [8] with added memristors and access transistors to enable the store and restore mechanisms similar to the traditional NVSRAM cell presented in [12]. In this embodiment, a novel nvXNOR cell design with enhanced store capabilities is disclosed. The basic store and restore mechanisms are below.

NVXNOR CELL Embodiment

Without loss of convention, it is assumed that the node Q in FIG. 7A stores Vdd and QB stores 0. FIG. 7B presents the store operation set and reset sequences.

The set mechanism: First, signal SWL turns ON, and BL bit line and BLB bit line are set to high. On the side of Q, no current flows between BL bit line and node Q, whereas on the side of QB, a current flows from BLB bit line to QB node, the low voltage storage node. Assuming that the resistor R_{R} was in the High Resistance State (HRS), the current flow sets memristor R_{R} to the Low Resistance State (LRS). On the other hand, the value of memristor R_{L}, i.e., memristor near high voltage storage node, will not be affected as there is no current flow on the left-hand side of the circuit in this embodiment.

The reset mechanism: During the second half of the store cycle, according to FIG. 7A, nodes BL/BLB are set to 0. The difference in voltage between node Q, the high voltage storage node, and BL bit line allows a flow of current in the left memristor R_{L}, this time in the opposite direction, from to BL bit line. The resistance as such is reset to the HRS.

Once the store operation is complete the supply voltage Vdd is turned off to power-off the device. Then, on the onset of power-up, the restore mechanism is invoked. Hence, initially, prior to the restore operation, both nodes Q and QB are at ground level. The restore operation relies on the stored memristor values to restore the cell nodes to their proper values. During restore, SWL is turned on and both BL and BLB signals are set to ground. Vdd voltage is then gradually increased. In the beginning, the Pull-Up (PU) transistors are both ON and are attempting to pull up Q and QB; on the other hand, the memristor devices are fighting to pull the nodes down to the ground. The side of the cell that has the memristor in the HRS (in this example R_{L}) will slow the path to ground facilitating for the pull-up device PUL to pull Q high. On the other hand, the side of the cell that has the memristor in the LRS (in this example R_{R}) will be successful at pulling its respective node (QB) to ‘0’. Thus, the HRS memristor (that was reset), R_{L}, helps restore its neighboring storage node, Q, to Vdd, and the set to LRS memristor (in this example), R_{R}, helps QB be restored to ‘0’. The cell feedback also plays a role to assist the flipping of the nodes to their proper values.

nvXNOR Revisiting Store Capabilities

For the case of reset in the traditional nvXNOR, the value of the voltage drop across the memristor is reduced. To elaborate on this, the ‘reset path’ section of the cell involving transistor PU_{L}, R_{R}, and RSW_{L} is examined in FIG. 7A. This path results in a voltage drop at node QB due to the voltage division between the resistance of PU_{L} and the other elements. This is especially visible because the path is starting typically from a small R_{L} memristor value that is to be reset. The reduced voltage across memristor R_{L} results in a weak and sometimes failed reset as will be elaborated below.

Increasing the size of the PU device alone will affect the write-ability of the cell. Hence, to improve the store, two new pull-up assist configurations are proposed to enhance the reset, as discussed below. Note that the set mechanism does not suffer as much from this problem due to two reasons. Typically the Pull-Down (PD) device is decently large in the SRAM cell, compared to the PU, and also the memristor, R_{R} in this example, is large and absorbs most of the voltage drop at the beginning of the set operation.

During Reset, the value of the voltage drop across the memristor is reduced. Typically SRAM devices are compact and have small PU devices. Increasing PU device can help but this affects SRAM cell writability and balance and degrade performance. The two new nvXNOR designs maintain SRAM cell integrity and enhance RESET store mechanism.

### Embodiment: nvXNOR with Enhanced Reset

nvXNOR enhRst Proposed Basic Embodiment

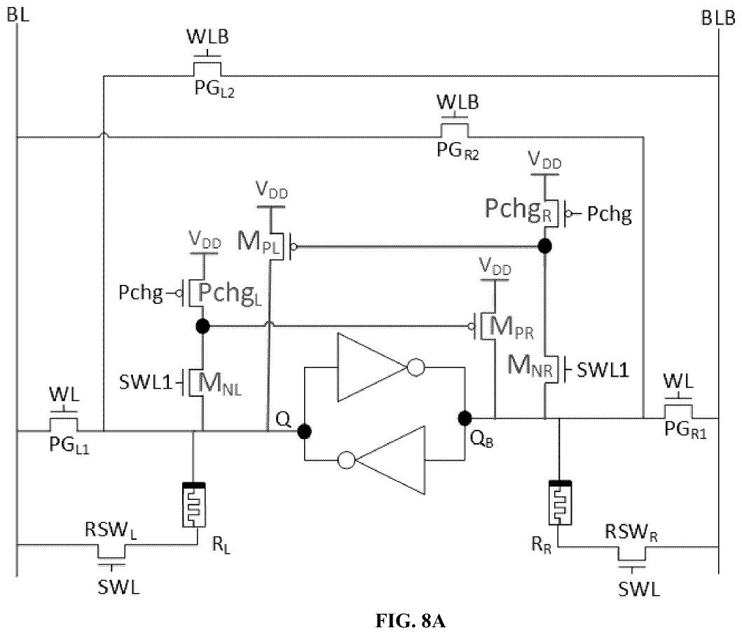

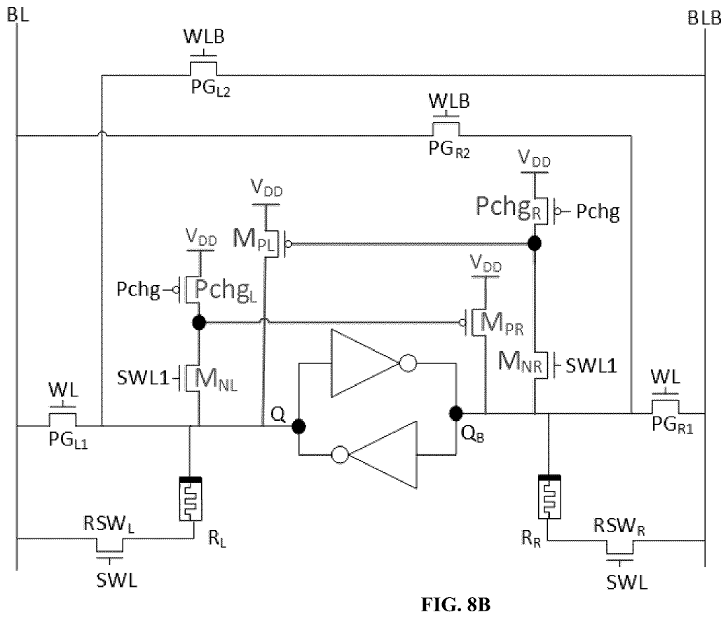

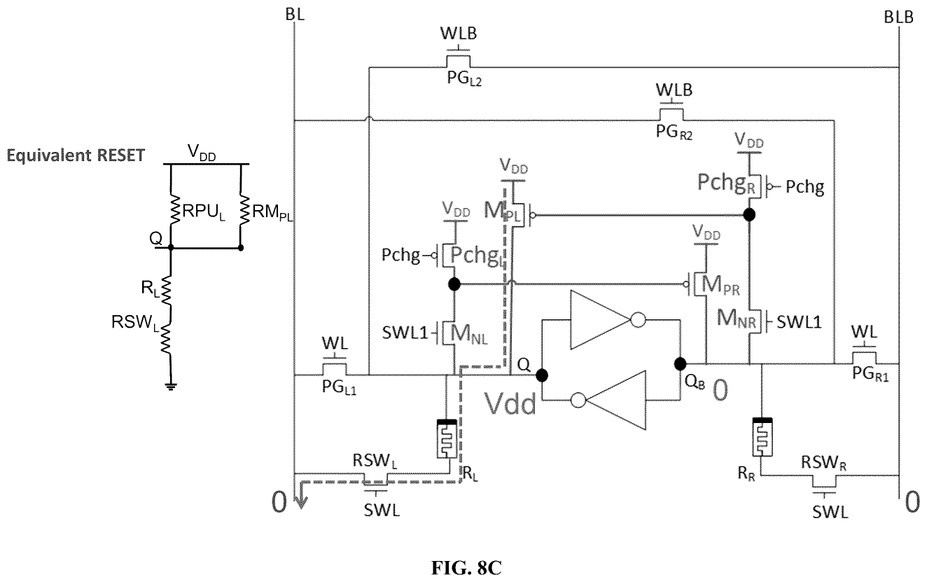

FIG. 8A presents the proposed nvXNOR cell with enhanced Reset capability (nvXOR enhRst). The cell offers additional pull-up capability (nvXNOR enhRst) comprised by the conditionally active PMOS transistors M_{P L} and M_{P R} that turn ON during reset operation only based on the stored node values. The inputs to these transistors are precharged and hence the transistors are turned off. They only turn on during reset.

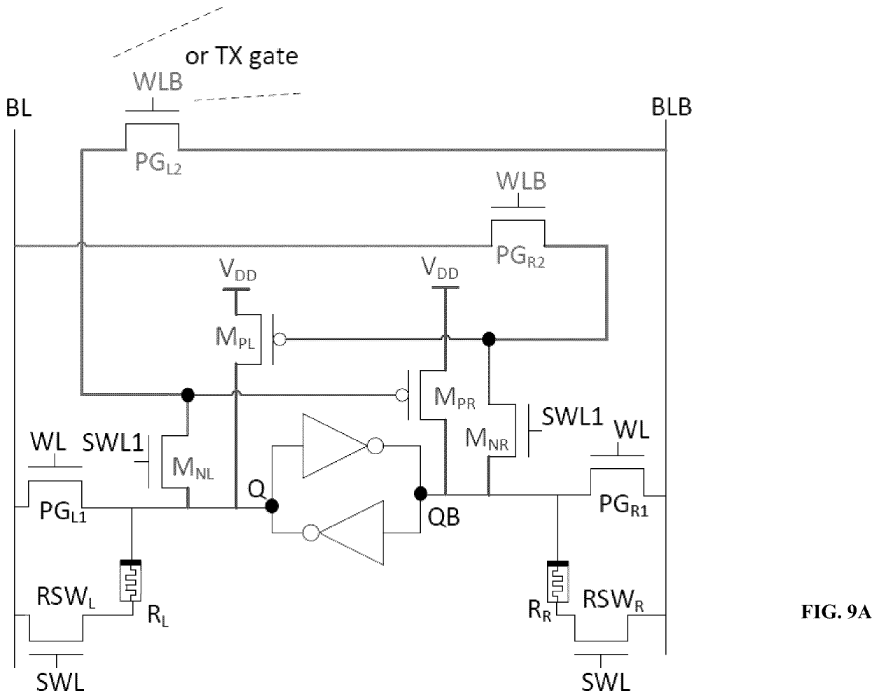

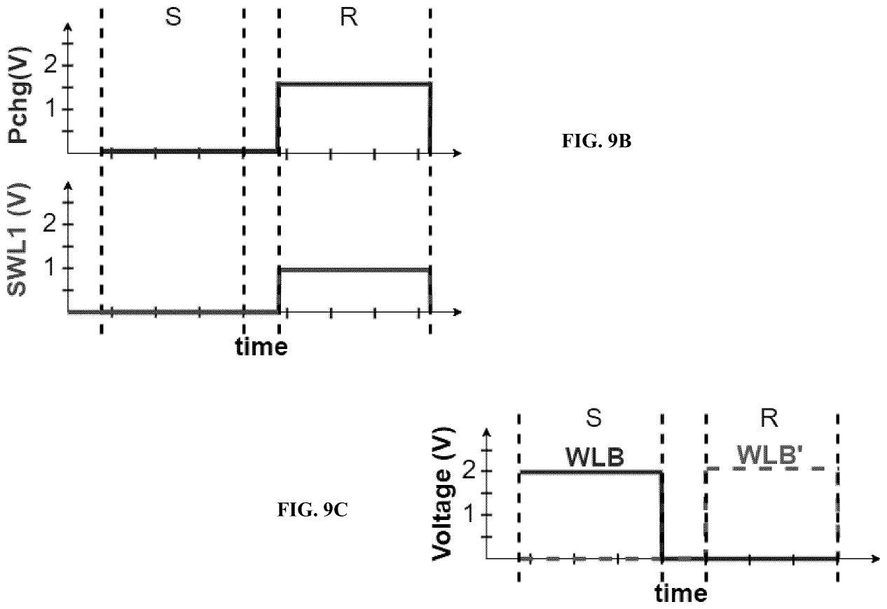

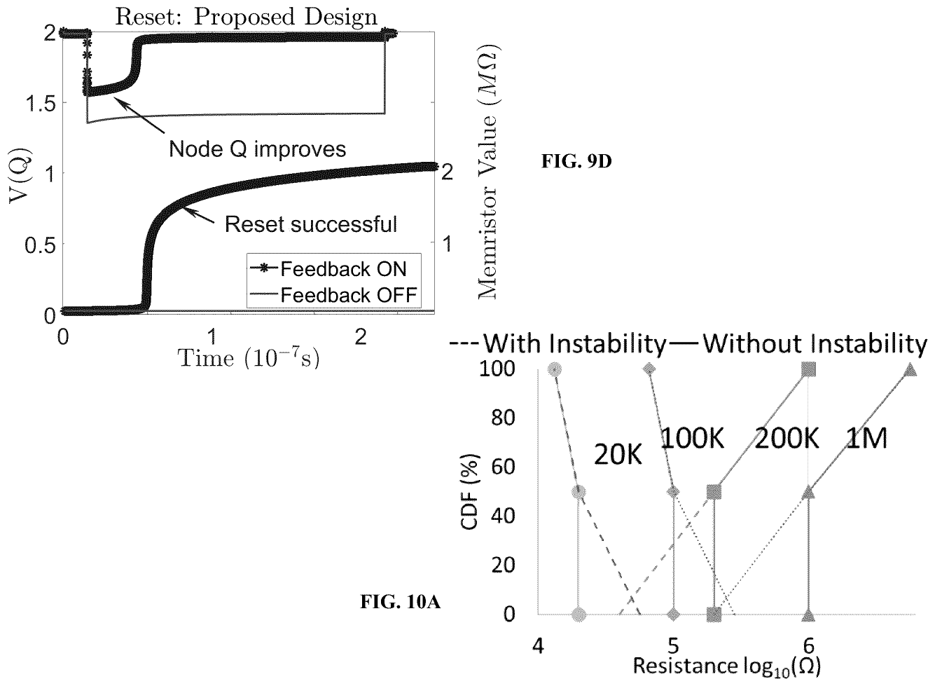

FIG. 9B presents the specific signals used for the set and reset mechanism in the (nvXNOR enhRst) cell. Without loss of convention, the node Q is assumed to store Vdd voltage whereas QB stores 0. While the set mechanism is similar to that of the traditional design, the reset mechanism is different. During reset, transistors M_{NR} and M_{NL} are turned ON. Node QB, which is zero, will be passed through transistor M_{NR} to the input of PMOS transistor M_{P L} and turn it on; PMOS transistor M_{P R} remains off. PMOS transistor M_{P L} will act as an additional pull-up device in parallel to PUL (the pull-up device of the bottom inverter) that assists it in holding Q high.

Hence, when the reset path is activated and BL bit line and BLB bit line are set to low, node Q will maintain a higher value compared to the traditional scenario. To illustrate, as shown in FIG. 9D, node Q includes two embodiments: a) when the feedback in the proposed design is off during reset (SWL1=0), and b) when the feedback is on. It is evident that node Q maintains a higher voltage in the proposed design. Furthermore, a successful memristor reset is achieved in this embodiment. This helps improve the reset mechanism overall. The setup of the transient simulations is discussed below.

The nvXNOR_enhRst Cell Overview is shown in FIG. 8A. Pre-charged PMOSs are off during reset. They facilitate turning off MPL and MPR during regular operation. The nvXNOR_enhRst Cell Reset Mechanism is shown in FIG. 8B. One of MPL and MPR turns on Conditionally during Reset only. When SWL 1 turns ON, the side storing zero will activate the Feedback PMOS. The nvXNOR_enhRst Cell Reset Mechanism is shown in FIG. 8C with the Enhanced RESET.

nvXNOR enhRst++ Embodiment

Alternatively, instead of adding precharge transistors, WLB access transistors are exploited to precharge the inputs to PMOS transistor MPL and PMOS transistor M_{PR} as illustrated in FIG. 9A. Herein, reduced signaling is presented in two embodiments. The reset path remains as described before. A simple pass gate implementation comprises WLB access transistors, MN, and MP transistors can be sized as discussed later in lieu of the removed precharge transistors as discussed in the experimental setup, which can help the feedback further.

A transmission gate implementation comprises inputs are access transistors WLB and WLB′ (to turn on PMOS transistor during reset) are used to precharge the node. The pair maintains the same area as the single access transistor WLB access device discussed in nvXNOR enhRst Proposed Basic Embodiment.

FIG. 9C presents the specific signals used for the set and reset mechanism for the proposed cell. Access transistors WLB and WLB′ thus precharge the inputs to the PMOS transistors M_{P L} and M_{P R}. During reset, these devices are turned off, and the reset proceeds. The minimal impact on SRAM cell functionality is achieved in this embodiment.

When writing the cell, WL access transistors, PG_{L1} and PG_{R1}, can be employed. Since PG_{L1} and PG_{R1} are maintained the same, the ratio of PU/PG during the write mechanism is maintained, and hence, the write-ability of the cell is not impacted.

During the read for the XNOR function, when WLB is active, SWL1 is also turned ON with it. The series path although introduces some delay, it reduces the injected noise on the cell. Furthermore, due to the absence of the precharge transistor, in this embodiment, the MN transistors (M_{NL} and M_{NR}) and WLB transistors, PG_{L2} and PG_{R2}, are sized to minimize the impact on the XNOR read via WLB.

The nvXNOR_enhRst++ Cell Overview is shown in FIG. 9. It does not require an explicit transistor for the precharge operation. A simple pass gate implementation: WLB access transistor used to precharge the node. A transmission gate implementation: whose inputs are WLB and WLB′ are used to precharge the node. Hence, WLB transistor can serve two purposes (xnor function and precharge function)

BNN Architecture

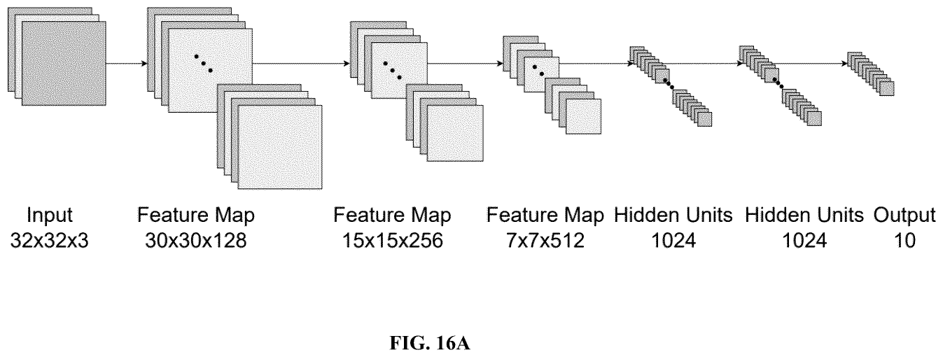

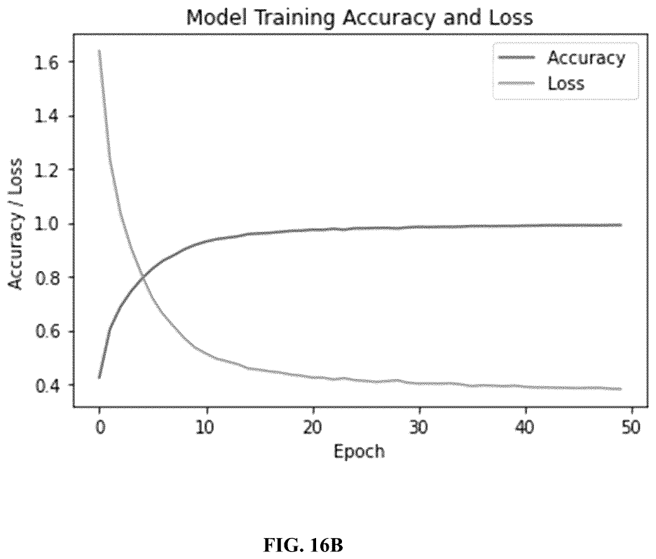

A fully connected BNN is constructed with the help of the open-source Python Larq Library [25]. As illustrated in FIG. 16A, the BNN consists of an input layer, five convolutional layers, two dense layers, and an output layer. After each convolutional layer, a Batch Normalization (BN) layer or a BN and a Max-Pooling (MP) layer are added. Table III shows the details of each layer in terms of the number of neurons, filter size, stride, size of the feature map, and the activation function used. The network is trained on CIFAR-10 dataset [24] that consists of 60000 (32×32) color images distributed equally among ten classes. The ten classes: airplane, automobile, bird, cat, deer, dog, frog, horse, ship, and truck are completely mutually exclusive. In this embodiment, the dataset is split into 40000 images for training, 10000 images for validation, and 10000 images for testing. The BNN is trained using an Adam optimizer with “categorical cross-entropy” as the loss function. The model is run for 50 epochs with a batch size of 50 and a learning rate of 0.01. The number of trainable parameters of this architecture is around 10.4 million.

FIG. 16B presents the model training accuracy and loss convergence. This BNN embodiment includes a 99.9% training accuracy and 83% validation accuracy which is consistent with prior art [26], [27]. The BNN is shown to have a 77.3% test error.

TABLE III
BNN Architecture Details

| | # | Filter | | Size of Feature | Activation |
|---|---|---|---|---|---|
| Layer | neurons | Size | Stride | Map | Function |
| Input | — | — | — | 32 × 32 × 3 | — |
| Conv 1 | 128 | 3 * 3 | 1 | 30 × 30 × 128 | STE-sign |
| Max Pooling 1 | — | 2 * 2 | 2 | 15 × 15 × 128 | — |
| Conv 2 | 256 | 3 * 3 | 1 | 15 × 15 × 256 | STE-sign |
| Conv 3 | 256 | 3 * 3 | 1 | 15 × 15 × 256 | STE-sign |
| Max Pooling 2 | — | 2 * 2 | 2 | 7 × 7 × 256 | — |
| Conv 4 | 512 | 3 * 3 | 1 | 7 × 7 × 512 | STE-sign |
| Conv 5 | 512 | 3 * 3 | 1 | 7 × 7 × 512 | STE-sign |
| Max Pooling 3 | — | 2 * 2 | 2 | 3 × 3 × 512 | — |
| Fully Connected 1 | — | — | — | 4608 | STE-sign |
| Fully Connected 2 | — | — | — | 1024 | STE-sign |
| Output | — | — | — | 10 | Softmax |

According to one embodiment, the model was constructed with open source software including Python Larq Library. Other open source software systems may be used according to other embodiments.

The Network is trained on CIFAR 10 Dataset. An Optimizer includes an “Adam” Loss Function: “categorical cross entropy”. Epochs include a 50 Batch Size: 50 Learning Rate: 0.01 as shown in FIG. 16A.

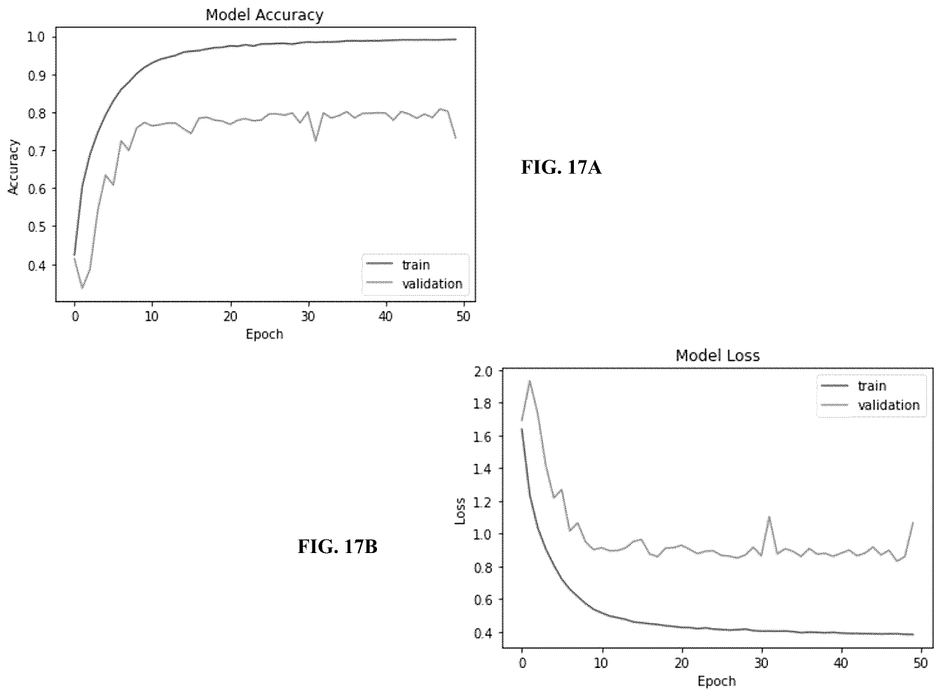

Model Accuracy and Loss Convergence is shown in FIGS. 17A and 17B.

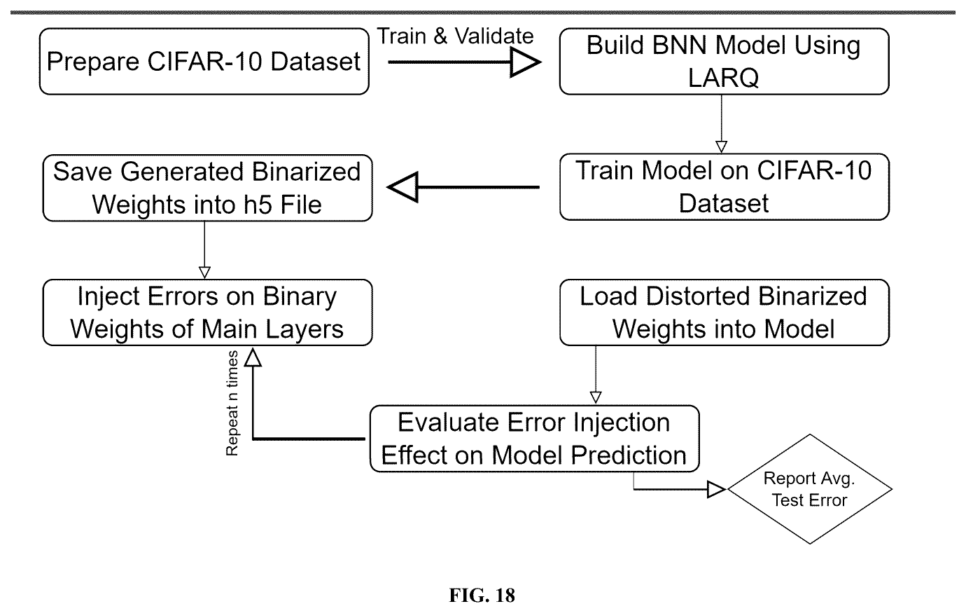

The flow diagram for the BNN Error Injection Algorithm is shown in FIG. 18. The BNN Error Injection Algorithm includes preparing the CIFAR-10 dataset, train and validate to Build BNN model using LARQ, train model on CIFAR-1p dataset, save generated binarized weights into h5 file, inject errors on binary weights of main layers and repeated n times, load distorted binarized weights into the model, evaluate error injection effect on model rejection and report the average and test the error.

Variation Method Embodiments

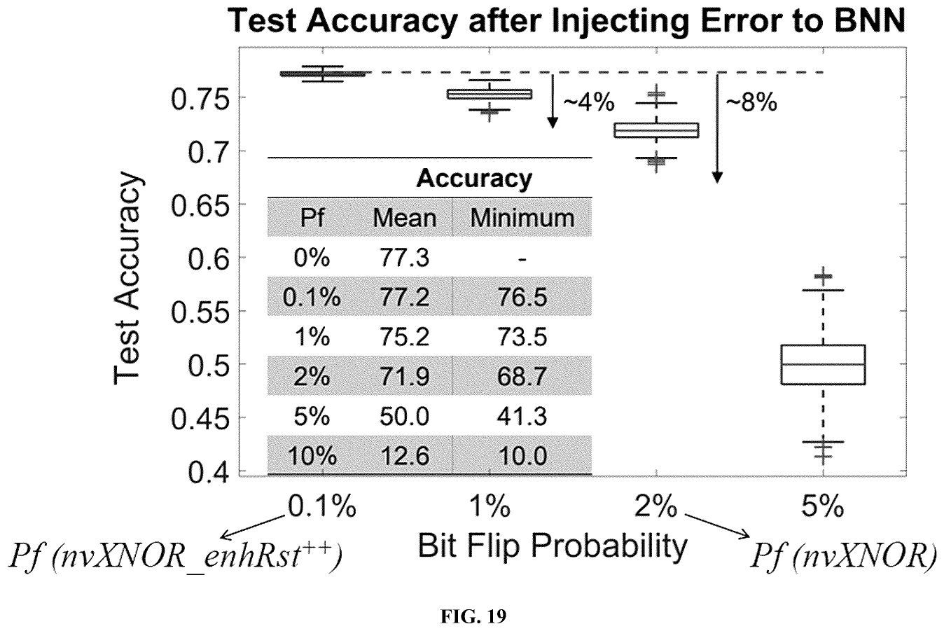

The impact of process variations on the BNN test error is studied in terms of the implications of a failed restore of the different cell designs. Hence, the weights of the trained BNN are altered to reflect the restore P_{f}. During testing, the generated binarized weights are subjected to different percentage error injections (0%, 0.1%, 1%, 2%, 5%, and 10%) representing the probability of fail of the memory element, and the errors are applied randomly. For each percentage error, the corresponding test accuracy is measured based on 300 Monte Carlo runs as shown in FIG. 19. P_{f}=0.1% that represents the probability of fail for the nvXNOR enhRst⁺⁺ cell with instability for the [20-200]KΩ window and σ_{V}_{ₜₕ}=30 mV results in ‘<1%’ degradation in the test error, whereas P_{f}=2% that represents the probability of fail for the traditional nvXNOR with instability for the same σ_{V}_{ₜₕ} and [33-200]KΩ window results in 8% degradation in the test error.

Test Accuracy After Error Injection is shown in FIG. 19. Error rate is tested in range of restore yield error of the proposed vs traditional designs cells.

As disclosed herein, the nvXNOR cells for BNN applications in energy harvesting processors. The proposed schemes for nvXNOR cell reveal a low store (reset) energy consumption with enhanced reset (achieving lower LRS values) allowing reasonable window range storage for the high endurance window. The enhanced reset capability results in enhanced restore yield due to the improved high endurance memristor window. The implemented error injection code for BNN showed for the proposed designs<1% reduction in test accuracy compared to 8% for the traditional design on the CIFAR 10 dataset.

In the embodiments disclosed, two versions of nvXNOR cells with enhanced Reset capability are shown and enabled. The design enhances the XNOR's embedded SRAM cell pull-up capability during reset without compromising the 6T cell aspect ratio. They further exploit the cross-coupled pass gate transistors to enable their functionality. When compared in terms to an equally sized version of the traditional cell, the designs demonstrate 30% and 38% improvement in energy and energy-delay product respectively. In turn, the enhanced reset capability results in an enhanced restore yield for the high endurance memristor window. An error-injection code for a BNN application is disclosed and the proposed design comprises a <1% reduction in test accuracy for the proposed designs compared to 8% for the traditional design or the CIFAR10 dataset. The size sram increases pullup and other based on aspect ratio max increase PU.

### EXAMPLES

The following examples are put forth so as to provide those of ordinary skill in the art with a complete disclosure and description of how the compounds, compositions, articles, devices and/or methods claimed herein are made and evaluated, and are intended to be purely exemplary of the invention and are not intended to limit the scope of what the inventors regard as their invention. However, those of skill in the art should, in light of the present disclosure, appreciate that many changes can be made in the specific embodiments which are disclosed and still obtain a like or similar result without departing from the spirit and scope of the invention.

Efforts have been made to ensure accuracy with respect to numbers (e.g., amounts, temperature, etc.), but some errors and deviations should be accounted for. Unless indicated otherwise, parts are parts by weight, temperature is in ° C. or is at ambient temperature, and pressure is at or near atmospheric.

### Example 1: Experimental Setup

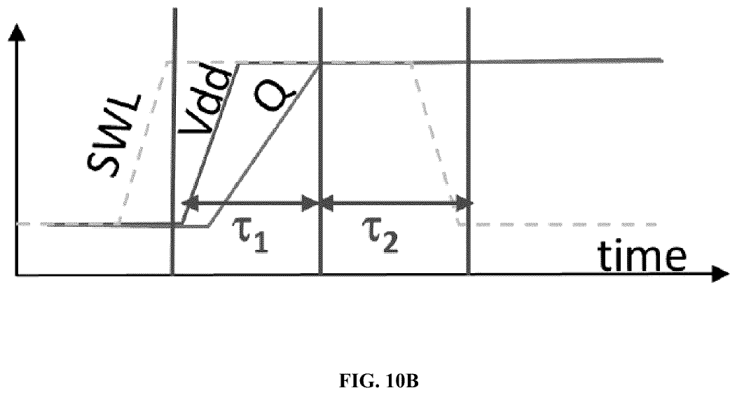

For purposes of our analysis, we rely on [21] for the RRAM device models and the 65 nm predictive technology device models [22]. During the Set and Reset mechanisms, a different set of voltage operating points is explored to compare the set and reset capabilities of the designs. For the Set mechanism, the SWL signal is swept between 2.5V and 3.2V whereas the BL/BLB signal is swept between 2V and 2.7V. Those values are around the nominal values proposed by [21]. In the Reset process, the SWL signal is swept between 0.5V and 1.5V whereas the Vdd is swept between 1.8V and 2.8V. Memristors R_{R}=HRS and R_{L}=LRS are set, and node Q is expected to rise during a proper restore [12]. Without loss of generality, the resistors in the LRS are assumed to take values over the range of [20KΩ-100KΩ], and resistors in the HRS take values over the range of [200KΩ-1 MΩ]. For purposes of the restore operation, the yield at Vdd=0.75V is studied for different device threshold voltage standard deviation values σ_{νt}={10, 15, 20, 30}mV. Memristor distributions presented in FIG. 10A are relied upon following model in [20]discussed above. For each memristor, two forms of the distribution are considered: (1) without instability (w/o INST) at <100 μs post verify and (2) with program instability (INST) measured at around 300 μs post program [20] [10], and affecting different percentage levels of the population. The high endurance window range [LRS-HRS]=[20-200]KΩ [10] is of interest. Table 3 presents the sizes of all the transistors used in the different designs.

Experimental Setup as shown in FIG. 10A including 65 nm (predictive technology model) PTM, Adopt High Endurance Ranges, LRS HRS (R_{L}-R_{R}) window ranges, targeting [20 k-200 K]. Memristor Variability and Instability with a yield Without Instability and a yield With Instability, with V_{dd}=0.75 V.

Objective is to study the effectiveness of the device in BNN application when operating in high endurance window.

Design Metrics

Evaluated the Set and Reset Mechanisms for the different cells is shown in FIG. 10B.

During Set: SWL:2.5V→3.2VwhileBL/BLB:2V→2.7V.

During Reset: SWL:0.5V→1.5VwhileVdd:1.8V→2.8V.

Table 3 shows the width of the transistors of the different cells. nvXNOR enhRst has the 6T transistors sized after a nominal SRAM cell. nvXNOR enhRst⁺⁺ has no dedicated precharge transistor and its width is distributed onto PG(WLB), MP and MN devices. nvXNOR SS represents a sized version of the nominal SRAM cell such as that all cells have the same area.

TABLE 3
Performance Evaluation for nvSRAM

| | PU | PD | PG | RSWL | MP | MN | PCHG | Area | Area ratio |
|---|---|---|---|---|---|---|---|---|---|
| nvSRAM | 90 | 150 | 120 | 130 | — | — | — | 980 | 1.00 |
| nvSRAM_enhRst | 90 | 120 | 150 | 130 | 90 | 90 | 90 | 1340 | 1.37 |

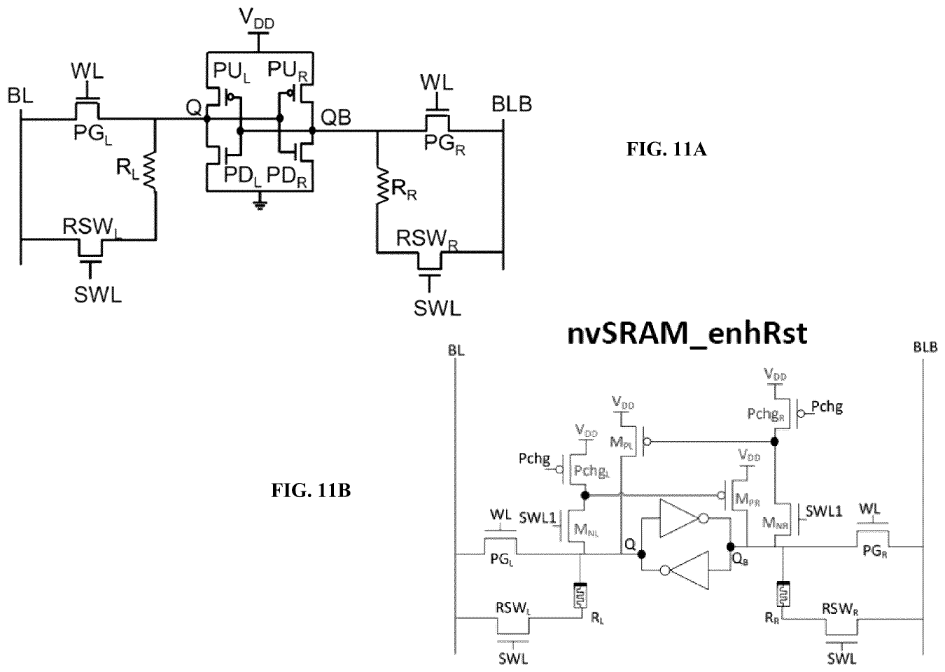

The nvSRAM is shown in FIG. 11A.

The nvSRAM_enhRst is shown in FIG. 11B.

Simulation Analysis normalized STORE Energy and EDP is shown in Table 4.

TABLE 4
Normalized Store Energy for Different nvSRAM Designs

| | 20K | 23K | 25K | 30K | 33K | 50K | 100K |
|---|---|---|---|---|---|---|---|
| nvSRAM_enhRst | 1 | 1 | 1 | 1 | 1 | 1 | 1 |
| nvSRAM | — | — | — | 33.9 | 22.5 | 8.35 | 3.94 |

TABLE 5
Normalized Store EDP for Different nvSRAM Designs

| | 20K | 23K | 25K | 30K | 33K | 50K | 100K |
|---|---|---|---|---|---|---|---|
| nvSRAM_enhRst | 1 | 1 | 1 | 1 | 1 | 1 | 1 |
| nvSRAM | — | — | — | 731.47 | 314.33 | 38.99 | 19.53 |

TABLE 6
Transistor width (nm) for nvXNOR cells

| | | | PG | PG | | | | | | Area |
|---|---|---|---|---|---|---|---|---|---|---|
| | PU | PD | (WL) | (WLB) | RRAM | MP | MN | PCHG | Area | ratio |
| nvXNOR | 90 | 150 | 120 | 120 | 130 | — | — | — | 1220 | 1 |
| nvXNOR_enhRst | 90 | 150 | 120 | 120 | 130 | 90 | 90 | 90 | 1760 | 1.44 |
| nvXNOR_enhRst++ | 90 | 150 | 120 | 150 | 130 | 120 | 120 | — | 1760 | 1.44 |
| nvXNOR_SS | 139 | 235 | 188 | 188 | 130 | — | — | — | 1760 | 1.44 |

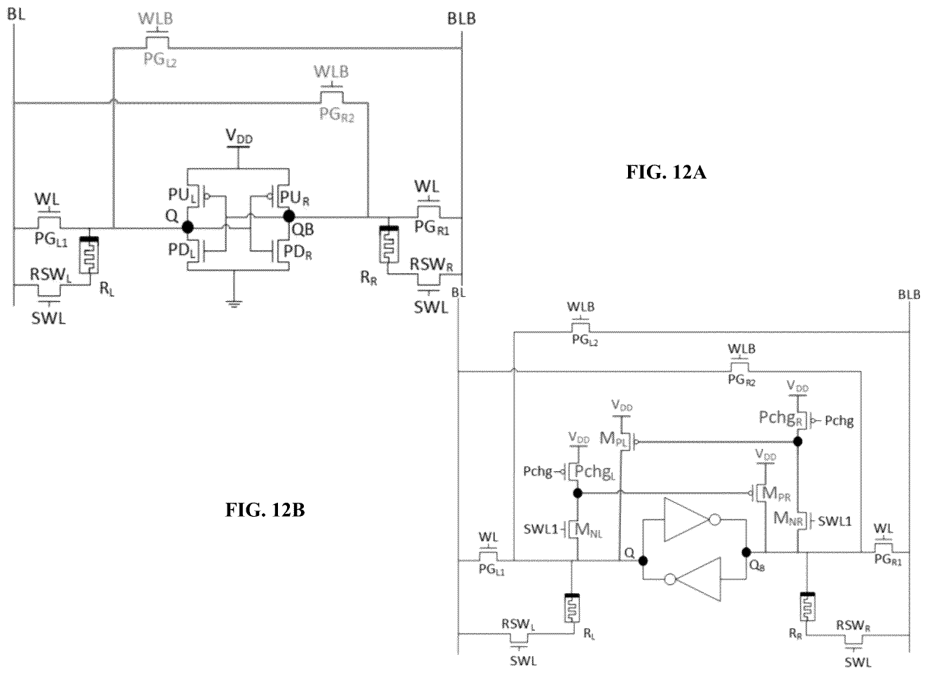

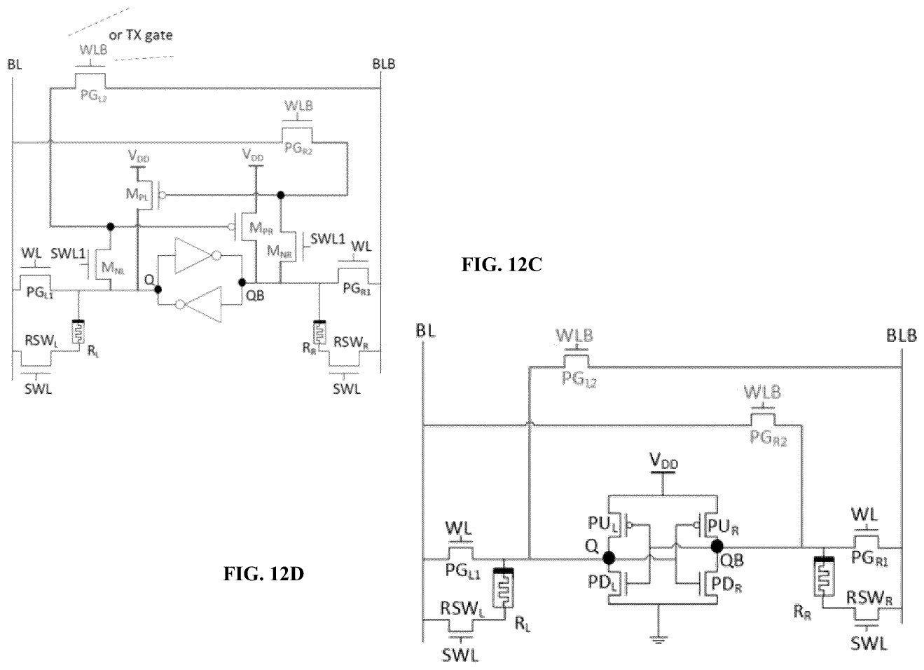

The nvXNOR is shown in FIG. 12A. The nvXNOR_enhRst is shown in FIG. 12B. The nvXNOR_enhRst++ is shown in FIG. 12C. The nvXNOR_SS (traditional cell with sized SRAM transistors to match the area of the proposed design) is shown in FIG. 12D.

nvXNOR_SS maintains device PU/PD/PG ratio, but increases area to match area of proposed design for comparison. This allows PU to undergo limited increase (while preserving ratio for proper functionality) Design Space Embodiments

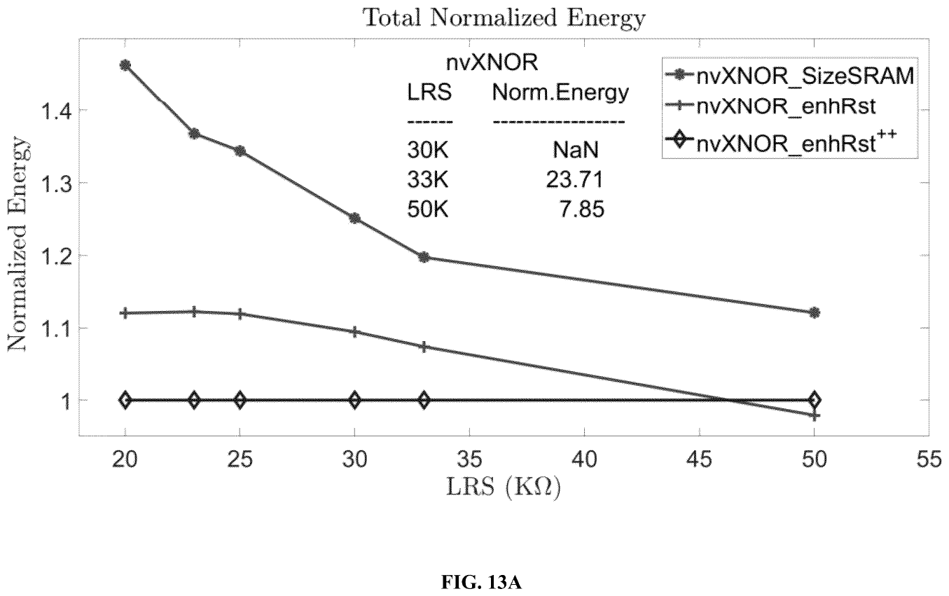

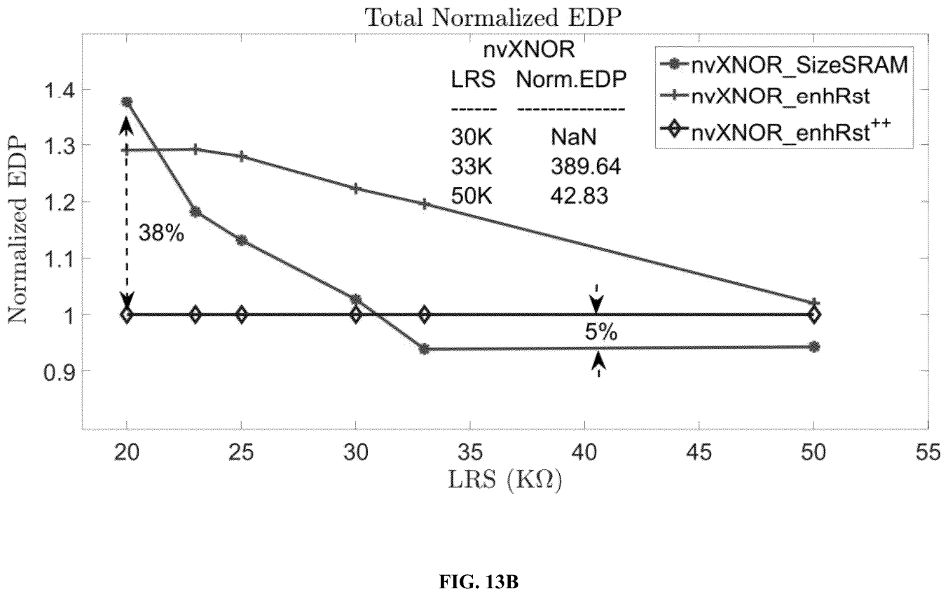

The energy and Energy Delay Product of the proposed designs are studied. FIG. 13A presents the normalized total set and reset energy for the different designs for different LRS values and fixed HRS value of 1 MΩ. The proposed nvXNOR enhRst⁺⁺ energy is up to 0.7× smaller than that of the nvXNOR SizeSRAM, with the nvXNOR enhRst coming second in terms of energy savings. This is attributed to the fact that the nvXNOR enhRst⁺⁺ benefits from the enhanced size of the M_{P L} and M_{P R} transistors. Most of the energy is dissipated when the memristor transitions through the lower states, and that the traditional nvXNOR consumes more than 23× energy for LRS values of 33 KΩ. FIG. 13B presents the normalized EDP for the designs under the same conditions stated above. The nvXNOR enhRst⁺⁺ has up to 0.72× lower EDP for the lower LRS ranges of interest. Furthermore, the traditional nvXNOR cell had more than two orders of magnitude larger EDP.

Simulation Analysis: Normalized STORE Energy is shown in FIG. 13A.

Simulation Analysis: Normalized STORE EDP is shown in FIG. 13B.

Restore Yield Analysis

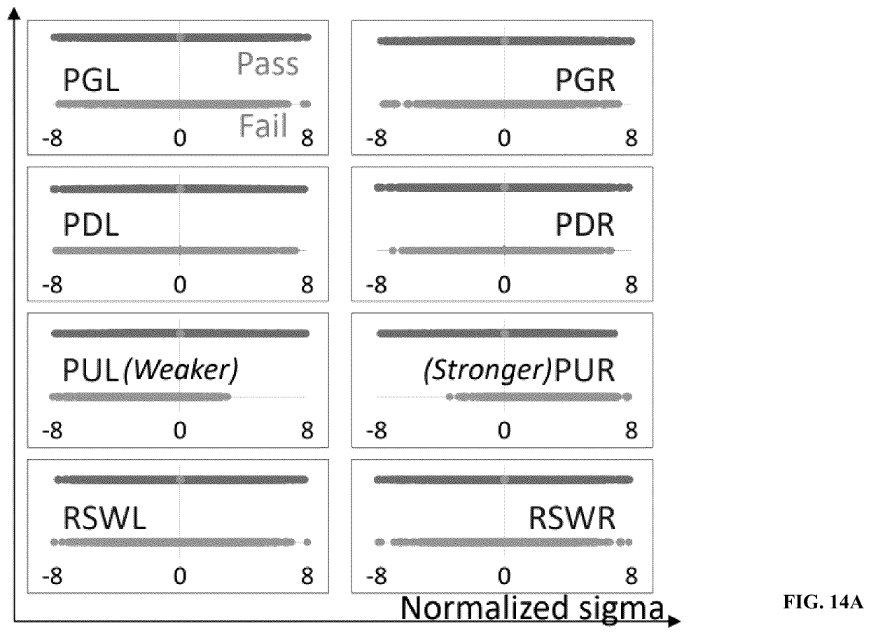

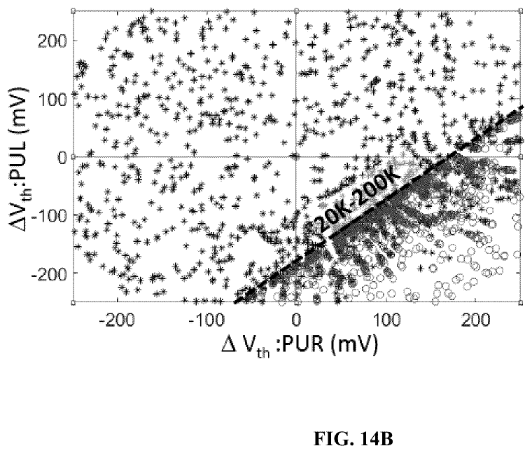

Initial simulations performed in 8-D device variability space without memristor variability indicated strong dependence of the restore mechanisms on the PU devices as shown in FIG. 14A for the traditional 8T NVXNOR cell; fails happen for weaker PUL and stronger PUR.

Hereon, the restore yield for the 4-D problem assuming variability in R_{L}, P_{R}, PUL and PUR is studied. Radial methods [23] fare relied upon or rare fail event estimation. The technique uniformly samples the unit hyper-sphere to obtain uniform directions. The distance of fail is used to obtain local fail probability which is averaged across all directions to obtain the effective cell fail probability P_{f}. The cell yield σ can then reported as using inverse Gaussian cdf of the fail probability. The memory array size, N_{cells}, can then be used to estimate the array yield, which in the absence of any redundancy, can be calculated as:

Yield=(1−P_{f})^{N}^{_{cells}} (1)

FIG. 14B presents the fail boundary for the [20-200]KΩ in the 2-D PUR/PUL space for the case w/o instability for the traditional cell. The sample points are obtained from the binary searches of the radial sampling.

Restore Yield Analysis is shown in FIG. 14A. Study restore yield assuming variability in RL, RR, PUL, and PUR.

The cell yield for the different designs is compared. The nvXNOR enhRst++ outperforms the yield of the nvXNOR SizeSRAM for all combinations of _Vth and memristor LRS-HRS window. The high endurance window of [20-200]KΩ also maintains a 10× HRS/LRS ratio and thus maintains a high restore yield compared to the smaller windows [10].

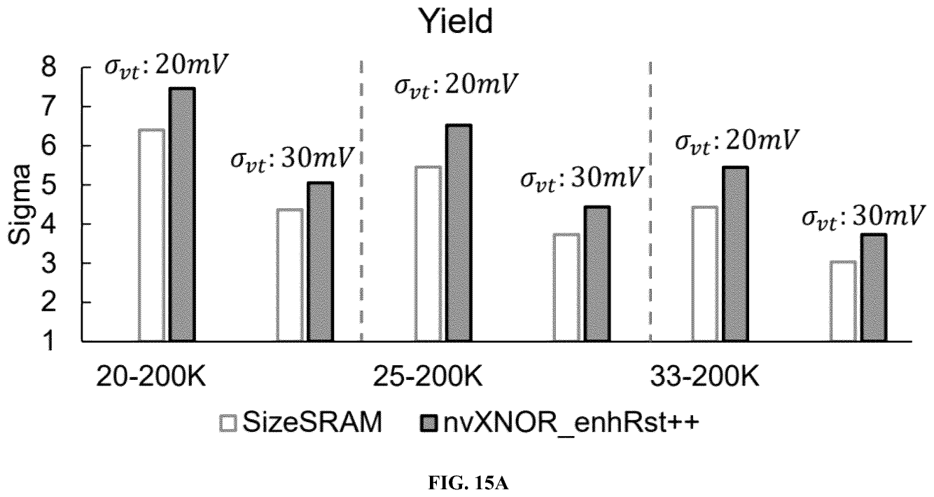

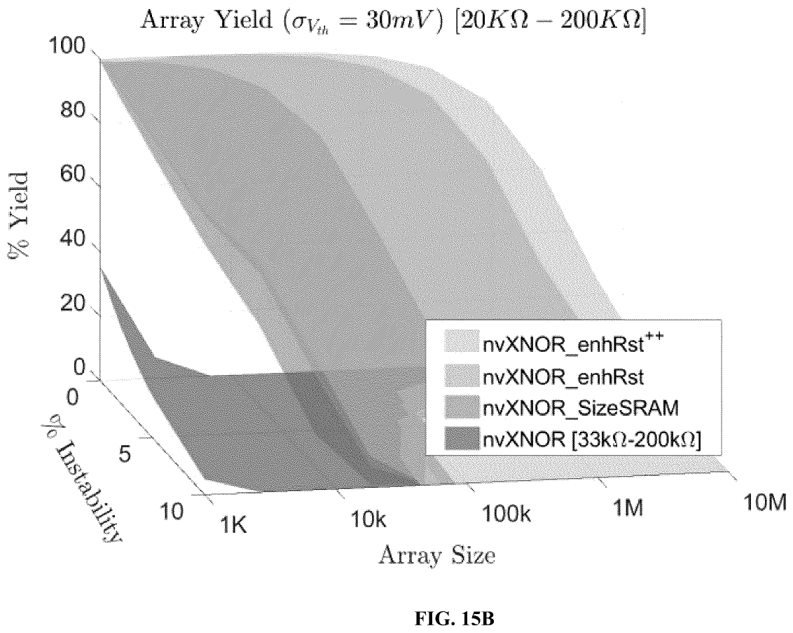

The array yield for the different designs in the presence of memristor instability is studied. FIG. 15B presents the percent yield for different designs as a function of in-stability ratios [10] and array sizes for σ_{V}_{ₜₕ}=30 mV. The nvXNOR enhRst++ offers enhanced yield in the presence of instability compared to the other designs. The traditional nvXNOR cell yield for a smaller LRSHRS window is presented, because the cell fails to reset for the [20-200]KΩ window with acceptable time and energy as presented earlier.

Simulation Analysis: Yield Plot without (instability) INS is shown in FIG. 15A. Simulation Analysis: Yield Plot with (instability) INS is shown in FIG. 15B.

System

As used in this application, the terms “component” and “system” are intended to refer to a computer-related entity, either hardware, a combination of hardware and software, software, or software in execution. For example, a component can be, but is not limited to being, a process running on a processor, a processor, an object, an executable, a thread of execution, a program, and/or a computer. By way of illustration, both an application running on a server and the server can be a component. One or more components can reside within a process and/or thread of execution, and a component can be localized on one computer and/or distributed between two or more computers.

Generally, program modules include routines, programs, components, data structures, etc., that perform particular tasks or implement particular abstract data types. Moreover, those skilled in the art will appreciate that the inventive methods can be practiced with other computer system configurations, including single-processor or multiprocessor computer systems, minicomputers, mainframe computers, as well as personal computers, hand-held computing devices, microprocessor-based or programmable consumer electronics, and the like, each of which can be operatively coupled to one or more associated devices.

The illustrated aspects of the innovation may also be practiced in distributed computing environments where certain tasks are performed by remote processing devices that are linked through a communications network. In a distributed computing environment, program modules can be located in both local and remote memory storage devices.

A computer typically includes a variety of computer-readable media. Computer-readable media can be any available media that can be accessed by the computer and includes both volatile and nonvolatile media, removable and non-removable media. By way of example, and not limitation, computer-readable media can comprise computer storage media and communication media. Computer storage media includes volatile and nonvolatile, removable and non-removable media implemented in any method or technology for storage of information such as computer-readable instructions, data structures, program modules or other data. Computer storage media includes, but is not limited to, RAM, ROM, EEPROM, flash memory or other memory technology, CD-ROM, digital versatile disk (DVD) or other optical disk storage, magnetic cassettes, magnetic tape, magnetic disk storage or other magnetic storage devices, or any other medium which can be used to store the desired information and which can be accessed by the computer.

Communication media typically embodies computer-readable instructions, data structures, program modules or other data in a modulated data signal such as a carrier wave or other transport mechanism, and includes any information delivery media. The term “modulated data signal” means a signal that has one or more of its characteristics set or changed in such a manner as to encode information in the signal. By way of example, and not limitation, communication media includes wired media such as a wired network or direct-wired connection, and wireless media such as acoustic, RF, infrared and other wireless media. Combinations of the any of the above should also be included within the scope of computer-readable media.

Software includes applications and algorithms. Software may be implemented in a smart phone, tablet, or personal computer, in the cloud, on a wearable device, or other computing or processing device. Software may include logs, journals, tables, games, recordings, communications, SMS messages, Web sites, charts, interactive tools, social networks, VOIP (Voice Over Internet Protocol), e-mails, and videos.

In some embodiments, some or all of the functions or process(es) described herein and performed by a computer program that is formed from computer readable program code and that is embodied in a computer readable medium. The phrase “computer readable program code” includes any type of computer code, including source code, object code, executable code, firmware, software, etc. The phrase “computer readable medium” includes any type of medium capable of being accessed by a computer, such as read only memory (ROM), random access memory (RAM), a hard disk drive, a compact disc (CD), a digital video disc (DVD), or any other type of memory.

### REFERENCES

[1] A. Krizhevsky, I. Sutskever, and G. E. Hinton, “Imagenet classification with deep convolutional neural networks,” Advances in neural information processing systems, vol. 25, 2012.
[2] G. Hinton, L. Deng, D. Yu, G. E. Dahl, A.-r. Mohamed, N. Jaitly, A. Senior, V. Vanhoucke, P. Nguyen, T. N. Sainath et al., “Deep neural networks for acoustic modeling in speech recognition: The shared views of four research groups,” IEEE Signal processing magazine, vol. 29, no. 6, pp. 82-97, 2012.
[3] H.-J. Yoo, “Deep convolution neural networks in computer vision: a review,” IEIE Transactions on Smart Processing and Computing, vol. 4, no. 1, pp. 35-43, 2015.
[4] J. Devlin, R. Zbib, Z. Huang, T. Lamar, R. Schwartz, and J. Makhoul, “Fast and robust neural network joint models for statistical machine translation,” in proceedings of the 52nd annual meeting of the Association for Computational Linguistics (Volume 1: Long Papers), 2014, pp. 1370-1380.
[5] S. Yin, Z. Jiang, J.-S. Seo, and M. Seok, “Xnor-sram: In-memory computing sram macro for binary/ternary deep neural networks,” IEEE Journal of Solid-State Circuits, vol. 55, no. 6, pp. 1733-1743, 2020.
[6] M. Courbariaux, Y. Bengio, and J.-P. David, “Binaryconnect: Training deep neural networks with binary weights during propagations,” Advances in neural information processing systems, vol. 28, 2015.
[7] M. Rastegari, V. Ordonez, J. Redmon, and A. Farhadi, “Xnor-net: Imagenet classification using binary convolutional neural networks,” in European conference on computer vision. Springer, 2016, pp. 525-542.
[8] R. Liu, X. Peng, X. Sun, W.-S. Khwa, X. Si, J.-J. Chen, J.-F. Li, M.-F. Chang, and S. Yu, “Parallelizing sram arrays with customized bitcell for binary neural networks,” in 2018 55th ACM/ESDA/IEEE Design Automation Conference (DAC). IEEE, 2018, pp. 1-6.
[9] X. Si, J.-J. Chen, Y.-N. Tu, W.-H. Huang, J.-H. Wang, Y.-C. Chiu, W.-C. Wei, S.-Y. Wu, X. Sun, R. Liu et al., “24.5 a twin-8t sram computation in-memory macro for multiple-bit cnn-based machine learning,” in 2019 IEEE International Solid-State Circuits Conference-(ISSCC). IEEE, 2019, pp. 396-398.
[10] Z. Swaidan, R. Kanj, J. El Hajj, E. Saad, and F. Kurdahi, “Rram endurance and retention: Challenges, opportunities and implications on reliable design,” in 2019 26th IEEE International Conference on Electronics, Circuits and Systems (ICECS). IEEE, 2019, pp. 402-405.
[11] Z. Wang, Y. Liu, A. Lee, F. Su, C.-P. Lo, Z. Yuan, J. Li, C.-C. Lin, W.-H. Chen, H.-Y. Chiu et al., “A 65-nm reram-enabled nonvolatile processor with time-space domain adaption and self-write-termination achieving>4faster clock frequency and >6higher restore speed,” IEEE Journal of Solid-State Circuits, vol. 52, no. 10, pp. 2769-2785, 2017.
[12] P.-F. Chiu, M.-F. Chang, C.-W. Wu, C.-H. Chuang, S.-S. Sheu, Y.-S. Chen, and M.-J. Tsai, “Low store energy, low vddmin, 8t2r nonvolatile latch and sram with vertical-stacked resistive memory (memristor) devices for low power mobile applications,” IEEE Journal of Solid-State Circuits, vol. 47, no. 6, pp. 1483-1496, 2012.
[13] A. Benoist, S. Blonkowski, S. Jeannot, S. Denorme, J. Damiens, J. Berger, P. Candelier, E. Vianello, H. Grampeix, J. Nodin et al., “28 nm advanced cmos resistive ram solution as embedded non-volatile memory,” in 2014 IEEE International Reliability Physics Symposium. IEEE, 2014, pp. 2E-6.
[14] M. Zhao, H. Wu, B. Gao, X. Sun, Y. Liu, P. Yao, Y. Xi, X. Li, Q. Zhang, K. Wang et al., “Characterizing endurance degradation of incremental switching in analog rram for neuromorphic systems,” in 2018 IEEE International Electron Devices Meeting (IEDM). IEEE, 2018, pp. 20-2.
[15] L. Chen, J. Li, Y. Chen, Q. Deng, J. Shen, X. Liang, and L. Jiang, “Accelerator-friendly neural-network training: Learning variations and defects in rram crossbar,” in Design, Automation & Test in Europe Conference & Exhibition (DATE), 2017. IEEE, 2017, pp. 19-24.
[16] F. M. Puglisi, L. Larcher, A. Padovani, and P. Pavan, “A complete statistical investigation of rtn in hfo 2-based rram in high resistive state,” IEEE Transactions on Electron Devices, vol. 62, no. 8, pp. 2606-2613, 2015.
[17] S. Yu, X. Guan, and H.-S. P. Wong, “On the switching parameter variation of metal oxide rram—part ii: Model corroboration and device design strategy,” IEEE Transactions on Electron Devices, vol. 59, no. 4, pp. 1183-1188, 2012.
[18] A. Fantini, L. Goux, R. Degraeve, D. Wouters, N. Raghavan, G. Kar, A. Belmonte, Y.-Y. Chen, B. Govoreanu, and M. Jurczak, “Intrinsic switching variability in hfo 2 rram,” in 2013 5th IEEE International Memory Workshop. IEEE, 2013, pp. 30-33.
[19] V. Karpov and D. Niraula, “Log-normal statistics in filamentary rram devices and related systems,” IEEE Electron Device Letters, vol. 38, no. 9, pp. 1240-1243, 2017.
[20] A. Fantini, G. Gorine, R. Degraeve, L. Goux, C.-Y. Chen, A. Redolfi, S. Clima, A. Cabrini, G. Torelli, and M. Jurczak, “Intrinsic program instability in hfo2 rram and consequences on program algorithms,” in 2015 IEEE International Electron Devices Meeting (IEDM). IEEE, 2015, pp. 7-5.
[21] X. Guan, S. Yu, and H.-S. P. Wong, “A spice compact model of metal oxide resistive switching memory with variations,” IEEE electron device letters, vol. 33, no. 10, pp. 1405-1407, 2012.
[22] Predictive echnology models (ptm). [Online]. Available: http://ptm.asu.edu/
[23] A. Issa, R. Kanj, A. Chehab, and R. Joshi, “Yield and energy tradeoffs of an nvlatch design using radial sampling,” in 2017 IEEE International Conference on IC Design and Technology (ICICDT). IEEE, 2017, pp. 1-4.
[24] A. Krizhevsky, G. Hinton et al., “Learning multiple layers of features from tiny images,” 2009.
[25] Larq. [Online]. Available: https://docs.larq.dev/larq/
[26] S. Liang, S. Yin, L. Liu, W. Luk, and S. Wei, “Fp-bnn: Binarized neural network on fpga,” Neurocomputing, vol. 275, pp. 1072-1086, 2018.
[27] L. Baruah, “Performance comparison of binarized neural network with convolutional neural network,” 2017.

All publications and patent applications mentioned in this specification are herein incorporated by reference to the same extent as if each individual publication or patent application was specifically and individually indicated to be incorporated by reference.

While the invention has been described in connection with various embodiments, it will be understood that the invention is capable of further modifications. This application is intended to cover any variations, uses or adaptations of the invention following, in general, the principles of the invention, and including such departures from the present disclosure as, within the known and customary practice within the art to which the invention pertains.

What is claimed is:

1. An nvXNOR Cell Design with enhanced store capability for Binary Neural Networks (BNN) in-memory compute applications, comprising: an nvXNOR cell including a low store energy consumption with an enhanced reset capability (nvXNOR enhRst) allowing storage for a high endurance window range, the nvXNOR cell including a conditionally active PMOS transistor M_{PL} and conditionally active PMOS transistor M_{PR} turn ON during reset operation only based on the stored node values; the inputs to the PMOS transistor M_{PL} and PMOS transistor M_{PR} are precharged and the transistors are turned off and the PMOS transistor M_{PL} and M_{PR} only turn on during reset.

2. The nvXNOR cell design of claim 1, wherein the enhanced reset capability results in enhanced restore yield due to the improved high endurance memristor window comprising a transistor M_{NR} and a transistor M_{NL} that are turned ON during reset; a node QB is zero and is passed through the transistor M_{NR} to the input of transistor M_{PL} and turning transistor M_{PL} on; the transistor M_{PR} remains off and the transistor M_{PL} acts as an additional pull-up device in parallel to PUL (the pull-up device of the bottom inverter) that assists in holding node Q high.

3. The nvXNOR cell design of claim 2, further comprising a reset path activated and a BL and a BLB are set to low, then the node Q maintains a higher value compared to the traditional scenario.

4. The nvXNOR cell design of claim 1, comprising an implemented error injection code taking as an input the analyzed probability of fail for a proposed design for the Binary Neural Networks (BNN) application includes a <1% reduction in test accuracy.

5. An nvXNOR enhRst⁺⁺ Cell Design comprising: a plurality of WLB access transistors to precharge the inputs to M_{P L} and M_{P R}; a simple pass gate implementation where the plurality of WLB access transistors, MN, and MP transistors are sized as discussed later in lieu of the removed precharge transistors the feedback further; or a transmission gate implementation: whose inputs are WLB and WLB′ to turn on PMOS transistor during reset and are used to precharge the node and the pair maintains the same area as the single WLB access device.

6. The nvXNOR enhRst⁺⁺ Cell Design of claim 5, further comprising precharging the inputs to the PMOS transistors M_{P L} and M_{P R}; during a reset, the PMOS transistors M_{P L} and M_{P R} are turned off, and the reset proceeds; when writing the cell, WL access transistors, PG_{L1} and PG_{R1} are employed; and PG_{L1} and PG_{R1} are maintained the same, the ratio of PU/PG during the write mechanism is maintained, and the write-ability of the cell is not impacted.

7. A NVXNOR cell store and restore system, comprising: a plurality of memristors and a plurality of access transistors operably coupled to a BL bit line and a BLB bit line to enable the store and restore mechanisms; a node Q stores Vdd and a node QB stores 0; a set mechanism includes a signal SWL turns ON and a BL signal and a BLB signal are set to high; no current flows between the BL bit line and the node Q; a current flows on the the node QB side from the BLB bit line to the QB node, the low voltage storage node; a memristor R_{R} is in the high resistance state (HRS), the current flow sets R_{R} to the low resistance state (LRS); the value of a memristor R_{L} is a near high voltage storage node, is not affected and there is no current flow.

8. The NVXNOR cell of claim 7, further comprising a reset mechanism including a second half of the store cycle, where the nodes BL/BLB are set to 0; the difference in voltage between node Q, the high voltage storage node, and BL allows a flow of current in the left memristor R_{L}, this time in the opposite direction, from to BL; the resistance is reset to the HRS.

9. The NVXNOR cell of claim 8, wherein the store operation is complete when the supply voltage Vdd is turned off to power-off the device; then, on the onset of power-up, the restore mechanism is invoked; prior to the restore operation, both nodes Q and QB are at a ground level; the restore operation relies on the stored memristor values to restore the cell nodes to a proper value; during restore, SWL is turned on and both BL and BLB signals are set to ground and Vdd is gradually increased; the Pull-Up (PU) transistors are both ON and are attempting to pull up Q and QB; the memristor devices are fighting to pull the nodes down to the ground; the side of the cell that has the memristor R_{L} in the HRS slows the path to ground facilitating for the pull-up device PUL to pull Q high; the side of the cell that has the memristor R_{R} in the LRS pulls its respective node (QB) to ‘0’; the HRS memristor R_{L} restores the storage node, Q, to Vdd, and the set to LRS memristor R_{R} restores QB to ‘0’.

10. The NVXNOR cell of claim 9, further comprising a reset path of the cell involving transistors PU_{L}, R_{R}, and RSW_{L}; the reset path results in a voltage drop at node QB due to the voltage division between the resistance of PU_{L} and the other elements; the reset path is starting from a small R_{L} memristor value that is to be reset; the reduced voltage across R_{L} results in a weak failed reset.
